(19) United States
(12) Patent Application Publication
(10) Pub. No.: US 2024/0234112 A1
(43) Pub. Date: Jul. 11, 2024

(54) IMAGE ANALYSIS OF PLASMA CONDITIONS

(71) Applicant: Lam Research Corporation, Fremont, CA (US)

(72) Inventors: Michal Danek, Cupertino, CA (US); Benjamin Allen Haskell, Pleasanton, CA (US); Kapu Sirish Reddy, Portland, OR (US); David Badt, Tigard, OR (US); Brian Joseph Williams, Tigard, OR (US); Paul Franzen, West Linn, OR (US); Karl Frederick Leeser, West Linn, OR (US); Jennifer Leigh Petraglia, Lake Oswego, OR (US); Yukinori Sakiyama, West Linn, OR (US); Kapil Sawlani, Ann Arbor, MI (US)

(21) Appl. No.: 18/572,075

(22) PCT Filed: Jul. 1, 2022
(86) PCT No.: PCT/US2022/073346

§ 371 Date: Dec. 19, 2023

Related U.S. Application Data
(60) Provisional application No. 63/263,232, filed on Oct. 28, 2021.
(60) Provisional application No. 63/203,001, filed on Jul. 2, 2021.

(51) Int. Cl. H01J 37/32; G06T 7/00; H01L 21/67

(52) U.S. Cl. CPC H01J 37/32972; G06T 7/0004; H01J 37/32926; H01J 37/32981; H01J 37/3299; H01L 21/67248; H01L 21/67253; H01J 37/32944; H01J 2237/221; H01J 2237/3321; H01J 2237/3341

(57) ABSTRACT

Multi-pixel sensors such as camera sensors may be configured to capture two-dimensional and/or three-dimensional images of the interior of a process chamber or other fabrication tool. The sensors may be configured to capture pixelated electromagnetic radiation intensity information from within the interior of such process chamber before, during, and/or after processing of a substrate in the chamber. Such sensors may also be utilized for control, predictive, and/or diagnostic applications.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

High performance plasma-assisted deposition and etch processes are important to the success of many semiconductor processing workflows. However, monitoring, controlling, and/or optimizing plasma processes can be difficult and time-consuming, oftentimes involving process engineers laboriously testing process parameters to empirically determine settings that produce a target result. Additionally, many techniques for in situ monitoring of plasma processes provide only limited information, such as information at the location of VI sensors.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Aspects of this disclosure pertain to systems that may include the following elements: (a) a semiconductor process chamber that includes a chamber wall, a plasma source, and at least two stations, where each station comprises a wafer support: (b) a first camera sensor optically coupled to a first optical access port of a first station of the process chamber, (c) a second camera sensor is optically coupled to the first optical access port of the process chamber or a second optical access port of the process chamber: and (d) logic configured to process signals from the first camera sensor and the second camera sensor to characterize one or more properties of a plasma in at least the first station of the process chamber.

Each station may additionally include one or more other components such as a heater and/or a process gas delivery component (e.g., a showerhead). In certain embodiments, the process chamber is a plasma deposition chamber and/or a plasma etch chamber. In certain embodiments, the process chamber comprises four or more stations.

In certain embodiments, the system additionally includes an optical fiber and/or a light pipe that optically couples the first camera sensor to the first optical access port. In further embodiments, the system includes a second optical fiber and/or a second light pipe that optically couples the first camera sensor to the second optical access port. In some cases, the first optical access port is an optical lens. In certain embodiments, the first optical access port includes a window having a maximum cross-sectional dimension of at most about 5 mm.

In certain embodiments, the logic is further configured to account for a feature of at least the second station of the process chamber. In some cases, the logic is configured to process the signals from the first camera sensor and from the second camera sensor in a multi-threaded process. In some implementations, the system additionally includes an edge computer for the process chamber, wherein the logic comprises instructions for executing on the edge computer.

In certain embodiments, the one or more properties of the plasma include a location of the plasma within chamber and/or within at least the first station. The location may include an edge or boundary of the plasma in first station. The location may include a centroid of the plasma within chamber and/or within the first station. The location may include a point or boundary of the plasma having a defined spectral characteristic. The location may include an integrated or summed optical intensity over a bounded region of interest within a field of view of the first camera sensor.

In certain embodiments, the one or more properties of the plasma include a pulse characteristic of the plasma. In certain embodiments, the logic is further configured to determine whether an arc or parasitic plasma occurs in the process chamber.

In certain embodiments, the one or more properties of the plasma comprise an identification of parasitic plasma.

In certain embodiments, the one or more properties of the plasma comprise an identification of hollow cathode discharge (HCD).

In certain embodiments, the logic is configured to characterize the one or more properties of the plasma in the first station of the process chamber. In such embodiments, the logic may be configured to account for a structural feature located in the second station of the process chamber. In certain implementations, the second station is adjacent to the first station in the process chamber. In some implementations, the structural feature of the located in the second station of the process chamber is on a line of sight from the optical access port of the first station that passes through the first station and the second station.

In certain embodiments, the system includes a non-camera sensor, and the logic is configured to employ signals from the non-camera sensor to characterize the one or more properties of a plasma in the process chamber.

In some implementations, camera sensors include at least two camera sensors located and/or oriented to capture images from at least two locations or two angles within the process chamber. For example, the first camera sensor may be located and/or oriented to capture first images from a first location or a first angle within the process chamber, and the second camera sensor may be located and/or oriented to capture second images from a second location or a second angle within the process chamber. In certain embodiments, the logic is further configured to process at least the first and second images to produce a spatial representation of the plasma.

In certain embodiments, the logic is configured to characterize the one or more properties of the plasma, as a function of time. In certain embodiments, the logic is configured to characterize pulses of the plasma.

In some cases, the system additionally includes a light source configured to provide lighting in the process chamber while the one or more camera sensors acquire images of the process chamber. In some cases, the system includes logic configured to synchronize the light source and the one or more camera sensors so that the one or more camera sensors acquire the images of the process chamber while the light source illuminates an interior region of the process chamber.

In certain embodiments, the first camera sensor is configured to capture indirect optical information from within the process chamber.

In certain embodiments, the logic is further configured to locate an edge of process chamber component and/or an edge of the plasma from one or more images provided by the first camera sensor.

In certain embodiments, the logic is further configured to use the one or more properties of the plasma to diagnose an actual or potential failure or fault with a component of the process chamber.

In certain embodiments, the logic is further configured to use the one or more properties of the plasma to characterize a process condition within the process chamber.

In certain embodiments, the logic is further configured to modify an operation in the process chamber based on the process condition within the process chamber.

In some examples, the process condition is a process gas composition, a process gas flow characteristic, a pressure within the process chamber, a temperature of one or more components of the process chamber, a plasma power, a plasma frequency, a geometric characteristic of any of the one or more components of the process chamber, or any combination thereof.

Aspects of this disclosure pertain to methods including the following operations: (a) obtaining a first image from a first camera sensor, wherein the first image is of at least a portion of a first station of a process chamber, where the process chamber comprises a chamber wall, a plasma source, and at least two stations, each comprising a wafer support: (b) obtaining a second image from a second camera sensor, wherein the second image is of a second region of the process chamber: and (c) characterizing one or more properties of a plasma in at least the first station of the process chamber, wherein the characterizing is based on the first image and the second image. In some implementations, the process chamber includes at least four stations.

In certain embodiments, characterizing one or more properties of the plasma in at least the first station accounts for a feature of at least a second station of the process chamber. In some embodiments, characterizing one or more properties of the plasma in at least the first station comprises processing the first image and the second image in a multi-threaded process. In some embodiments, characterizing one or more properties of the plasma in at least the first station comprises processing the first image and the second image in an edge computer for the process chamber.

In certain embodiments, characterizing the one or more properties of the plasma in at least the first station comprises identifying one or more contours of elements associated with the first station in the first image and/or the second image. In some examples, the one or more elements comprise: a showerhead in the first station, a pedestal in the first station, chamber walls of the first station, or any combination thereof. In some examples, identifying the one or more contours comprises performing edge detection on the first image and/or the second image. In some examples, the one or more properties comprise identification of hollow cathode discharge (HCD) occurrences, and the method further comprises clustering pixels of the first image and/or the second image into a plurality of categories, at least one category of the plurality of categories corresponding to HCD occurrences.

In certain embodiments, characterizing the one or more properties of the plasma comprises providing the first image and/or the second image to a trained machine learning model configured to perform segmentation on the first image and/or the second image. In some examples, the trained machine learning model is a U-Net architecture.

Various plasma properties may be characterized. In certain embodiments, the one or more properties of the plasma include a location of the plasma within chamber and/or within at least the first station. As examples, the location may include an edge or boundary of the plasma in first station. In certain embodiments, the location includes a centroid of the plasma within chamber and/or within the first station. In certain embodiments, the location includes a point or boundary of the plasma having a defined spectral characteristic. In certain embodiments, the location includes an integrated or summed optical intensity over a bounded region of interest within a field of view of the first camera sensor. In certain embodiments, the one or more properties of the plasma include a pulse characteristic of the plasma.

In certain embodiments, characterizing one or more properties of the plasma in at least the first station includes accounting for a structural feature located in a second station of the process chamber, wherein the second structural feature is identified in the second image. In some cases, the structural feature located in the second station of the process chamber is on a line of sight that includes at least a portion of the first station and at least a portion of the second station.

In certain embodiments, characterizing one or more properties of the plasma in at least the first station includes analyzing signals from the non-camera sensor of the process chamber. In certain embodiments, characterizing one or more properties of the plasma includes determining whether an arc or parasitic plasma occurs in the process chamber.

In some implementations, this additionally includes producing a spatial representation of the plasma. In certain embodiments, characterizing one or more properties of the plasma includes characterizing the one or more properties of the plasma as a function of time. In certain embodiments, characterizing one or more properties of the plasma includes characterizing pulses of the plasma.

In some implementations, the method additionally includes synchronizing a light source and image capture of the first camera sensor so that the first camera sensor acquires the first image while the light source illuminates an interior region of the process chamber.

In some implementations, the method additionally includes locating an edge of a process chamber component from the first image or the second image.

In some implementations, the method additionally includes using the one or more properties of the plasma to diagnose an actual or potential failure or fault with a component of the process chamber. In some implementations, the method additionally includes using the one or more properties of the plasma to characterize a process condition within the process chamber. In some implementations, the method additionally includes modifying an operation in the process chamber based on the process condition within the process chamber. As examples, the process condition may be a process gas composition, a process gas flow characteristic, a pressure within the process chamber, a temperature of one or more components of the process chamber, a plasma power, a plasma frequency, a geometric characteristic of any of the one or more components of the process chamber, or any combination thereof.

Certain aspects of this disclosure pertain to systems that include the following elements: (a) a semiconductor process chamber including a chamber wall and a plasma source: (b) one or more optical access ports in the chamber wall: (c) one or more camera sensors optically coupled to the one or more optical access ports in a manner that can capture a two-dimensional image or a three-dimensional image of one or more features of a plasma located within the process chamber: and (d) logic configured to process signals from the one or more camera sensors to (i) characterize one or more properties of the plasma at a first region of interest within the process chamber, and (ii) characterize the one or more properties of the plasma at a second region of interest within the process chamber.

In some embodiments, the two-dimensional image or the three-dimensional image of the one or more features of the plasma is an image of the plasma between a wafer support and a showerhead. In some embodiments, the two or more regions of interest within the process chamber may be separated from one another along an axis parallel to a planar surface of the wafer support and/or the showerhead. In some embodiments, the two or more regions of interest within the process chamber are separated from one another at a radial and/or azimuthal position on the wafer support and/or the showerhead.

In certain embodiments, the logic is configured to characterize the one or more properties of the plasma as a function of time, at the two or more regions of interest within the process chamber. As an example, the logic may be configured to characterize pulses of the plasma at the two or more regions of interest within the process chamber. In certain embodiments, the one or more camera sensors comprise at least two camera sensors located and/or oriented to capture images from at least the first region of interest and the second region of interest within the process chamber. In some cases, the logic is further configured to process the images from at least the first region of interest and the second region of interest to produce a spatial representation of the plasma in at least the first region of interest and/or the second region of interest within the process chamber.

In some implementations, the system includes a light source configured to provide lighting in the process chamber while the one or more camera sensors acquire images of the process chamber. In some cases, the system additionally includes logic configured to synchronize the light source and the one or more camera sensors so that the one or more camera sensors acquire the images of the process chamber while the light source illuminates an interior region of the process chamber.

In certain embodiments, the logic is further configured to determine whether an arc or parasitic plasma occurs in the first region of interest and/or in the second region of interest.

Certain aspects of this disclosure pertain to methods that include the following operations: (a) receiving image data from the one or more camera sensors disposed on or in a semiconductor process chamber: (b) characterizing one or more properties of a plasma at a first region of interest within the process chamber: and (c) characterizing the one or more properties of the plasma at a second region of interest within the process chamber. The process chamber may include a plasma source, a chamber wall, one or more optical access ports in the chamber wall, wherein the one or more camera sensors are optically coupled to the one or more optical access ports in a manner that can capture a two-dimensional image or a three-dimensional image of one or more features of a plasma located within the process chamber

In certain embodiments, the two-dimensional image or the three-dimensional image of the one or more features of the plasma is an image of the plasma between a wafer support and a showerhead. In some implementations, the two or more regions of interest within the process chamber are separated from one another along an axis parallel to a planar surface of the wafer support and/or the showerhead. In some implementations, the two or more regions of interest within the process chamber are separated from one another at a radial and/or azimuthal position on the wafer support and/or the showerhead.

In certain embodiments, characterizing the one or more properties of the plasma at the first region of interest includes characterizing the one or more properties of the plasma as a function of time. In certain embodiments, characterizing the one or more properties of the plasma at the first region of interest includes characterizing pulses of the plasma at the first region of interest within the process chamber.

In certain embodiments, methods additionally include determining whether an arc or parasitic plasma occurs in the first region of interest and/or in the second region of interest. In certain embodiments, the one or more camera sensors include at least two camera sensors located and/or oriented to capture images from at least the first region of interest and the second region of interest within the process chamber. In some cases, methods additionally include processing the images from at least the first region of interest and the second region of interest to produce a spatial representation of the plasma in at least the first region of interest and/or the second region of interest within the process chamber.

In certain embodiments, methods additionally include synchronizing a light source and the one or more camera sensors so that the one or more camera sensors acquire the images of the process chamber while the light source illuminates an interior region of the process chamber.

Some aspects of this disclosure pertain to systems that include the following elements: (a) a process chamber including a chamber wall and a plasma source: (b) an optical access port in the chamber wall: (c) a camera sensor optically coupled to the optical access port: (d) an auxiliary sensor configured to sense a thermal, optical, and/or electrical condition in the process chamber, wherein the auxiliary sensor is not a camera sensor, and (e) logic configured to process signals from the camera sensor and the auxiliary sensor to characterize one or more properties of a plasma in the process chamber. In some implementations, the process chamber is an integrated circuit fabrication process chamber such as a plasma assisted deposition or etch chamber.

In certain embodiments, the auxiliary sensor is a voltage and/or current sensor. In some implementations, the one or more properties of a plasma include plasma potential and/or plasma electron temperature.

In certain embodiments, the auxiliary sensor is an optical metrology sensor. In certain embodiments, the auxiliary sensor is a spectroscopic sensor. In some embodiments, the one or more properties of a plasma comprise chemical species within the plasma. In certain embodiments, the auxiliary sensor is an optical emission spectroscopy sensor or a voltage/current sensor configured to sense the voltage or current associated with the plasma.

In some systems, the camera sensor is a hyperspectral camera sensor. In certain embodiments, the camera sensor is configured to capture and discriminate between optical signal in at least two of the following spectral regions: UV, visible, IR.

In some systems, the logic is further configured to determine whether an arc or parasitic plasma occurs in the process chamber. In certain embodiments, the logic is configured to characterize the one or more properties of the plasma, as a function of time. For example, the logic may be configured to characterize pulses of the plasma.

Certain aspects of this disclosure pertain to methods that include the following operations: (a) receiving signals from a camera sensor optically coupled to a process chamber, comprising a chamber wall and a plasma source: (b) receiving signals from an auxiliary sensor that is not a camera sensor: and (c) characterizing one or more properties of a plasma in the process chamber based at least on part with the signals from camera sensor and the auxiliary sensor.

In some implementations, the signals from the auxiliary sensor comprise current and/or voltage signals from a voltage and/or current sensor. In some cases, the one or more properties of the plasma comprise plasma potential and/or plasma electron temperature. In some implementations, the auxiliary sensor is an optical emission spectroscopy sensor or a voltage/current sensor configured to sense a voltage or a current associated with the plasma.

In certain embodiments, the signals from the auxiliary sensor include optical metrology signals from an optical metrology sensor. In certain embodiments, the auxiliary sensor is a spectroscopic sensor. In such cases, the one or more properties of the plasma may include identities or concentrations of chemical species within the plasma.

In certain embodiments, the camera sensor is a hyperspectral camera sensor. In certain embodiments, the camera sensor is configured to capture and discriminate between optical signal in at least two of the following spectral regions: UV, visible, IR.

In certain embodiments, characterizing one or more properties of a plasma includes characterizing the one or more properties of the plasma, as a function of time. In certain embodiments, characterizing one or more properties of a plasma includes characterizing pulses of the plasma.

In some cases, a method additionally includes determining whether an arc or parasitic plasma occurs in the process chamber.

These and other features of the disclosure will be presented in more detail below.

### BRIEF DESCRIPTION OF THE DRAWINGS

FIG. 1A shows a fabrication tool for depositing or etching a film on or over a substrate utilizing a plasma process: the tool includes a camera sensor.

FIG. 1B presents a schematic view of an implementation of a multi-station processing tool: the tool includes four camera sensors.

FIG. 1C presents a top view of an electronic device fabrication system having four multi-station fabrication tools, one of which includes camera sensors.

FIG. 1D presents an example of spectral sensitivity ranges for “standard” (visible-sensitive), IR-sensitive, and UV-sensitive sensor elements in a camera sensor or a combination of camera sensors.

FIG. 1E schematically depicts a process chamber with a camera oriented to capture images along a horizontal line of sign into the chamber interior.

FIG. 1F schematically depicts a process chamber with cameras oriented to capture images along vertical lines of sight into the chamber interior.

FIG. 1G illustrates an embodiment in which a camera sensor is mounted to access a view port or optical access aperture of a chamber wall in a fabrication tool.

FIG. 2 presents a camera image of a plasma in a gap between a showerhead and a wafer pedestal. Image analysis is performed separately on three regions of interest distributed horizontally (or radially) within the gap.

FIG. 3 presents a camera image of a plasma in a gap between a showerhead and a wafer pedestal. Image analysis is performed separately on four regions of interest distributed vertically within the gap.

FIGS. 4A and 4B illustrate hypothetical time-varying plasma intensities captured by a camera sensor on a fabrication tool. The plasma intensity profiles indicate times when the plasma is off, times when the plasma is on at a constant value, and times when the plasma is on and pulsing.

FIG. 5 presents a plot of time-based intensity variations at the four regions of interest illustrated in FIG. 3. As illustrated by the periodic rising and falling of the intensity values, the plasma is pulsing.

FIG. 6 illustrates images related to characterizing plasma health within a process station in accordance with some embodiments.

FIG. 7 is a flowchart of an example process for characterizing plasma health within a process station in accordance with some embodiments.

FIGS. 8A and 8B illustrate images related to identifying parasitic plasma occurrences in accordance with some embodiments.

FIG. 9 is a flowchart of an example process for identifying parasitic plasma occurrences in accordance with some embodiments.

FIG. 10 is an image related to identifying hollow cathode discharge (HCD) occurrences in accordance with some embodiments.

FIG. 11 is a flowchart of an example process for identifying HCD occurrences in accordance with some embodiments.

FIG. 12 depicts example plots that illustrate relationships between plasma intensity, plasma power, and pressure in accordance with some embodiments.

FIG. 13 is a block diagram of an example computing environment suitable for use in implementing some embodiments of the present disclosure.

### DETAILED DESCRIPTION

### Introduction and Context

Aspects of this disclosure pertain to multi-pixel sensors such as camera sensors configured to capture images of the interior of a process chamber or other fabrication tool. The sensors may be configured to capture pixelated electromagnetic radiation intensity information from within the interior of such process chamber before, during, and/or after processing of a substrate in the chamber. Such sensors may also be utilized during nonproduction operations such as chamber cleaning operations and chamber diagnostic applications.

The electromagnetic radiation intensity that is captured by the camera sensor may arise from various sources such as plasmas, thermal energy, and/or optical probing or other stimulus of features within a process chamber.

The captured data may be in the form of radiation intensity values provided as a function of location within the process chamber. Collectively these values may form an image, such as an image or a region within the process chamber. In some embodiments, the captured intensity values are provided as a function of wavelength. The radiation may be provided over any one or more ranges of the electromagnetic spectrum such as all or a portion of the ultraviolet, visible, and/or infrared regions. In some embodiments, the captured radiation information is obtained over a time span. In such cases, the radiation information may be captured at discrete intervals, which may correspond to a frame rate of a camera sensor. The information may be captured by sampling at a rate sufficient to capture anticipated variations in a condition within the process chamber such as pulses or other temporal variations of a plasma. It should be noted that, in some cases, a camera frame rate may be less than a plasma pulse rate.

The process chamber or other fabrication tool may take any of various forms. Some examples are presented later in this disclosure. In some embodiments, the process chamber is used in fabricating an electronic device such as an integrated circuit on a semiconductor substrate. In some embodiments, the process chamber is configured to deposit one or more materials on a substrate. In some embodiments, the process chamber is configured to etch material from a substrate contained within the process chamber. In some embodiments, the process chamber is configured to deposit material and/or etch material using a plasma mediated process. In some embodiments, the process chamber is configured to deposit material and/or etch material by a thermally mediated process. Images of a fabrication tool may be captured while the tool is active or idle. An active tool may be engaged in fabricating electronic devices or some other process such as chamber cleaning.

Some fabrication tools comprise a chamber having two or more stations, with each station configured to process a substrate. Thus, for example, a multi-station fabrication tool may simultaneously process two, three, four, or more substrates concurrently, in the same chamber. In some embodiments, each station in multi-station fabrication tool has its own wafer support component (e.g., a pedestal and/or wafer chuck), its own process gas delivery component (e.g., a showerhead), and/or its own plasma source (e.g., a coil or capacitor plates). The disclosure is not limited to multi-station chambers: many embodiments pertain to single station chambers.

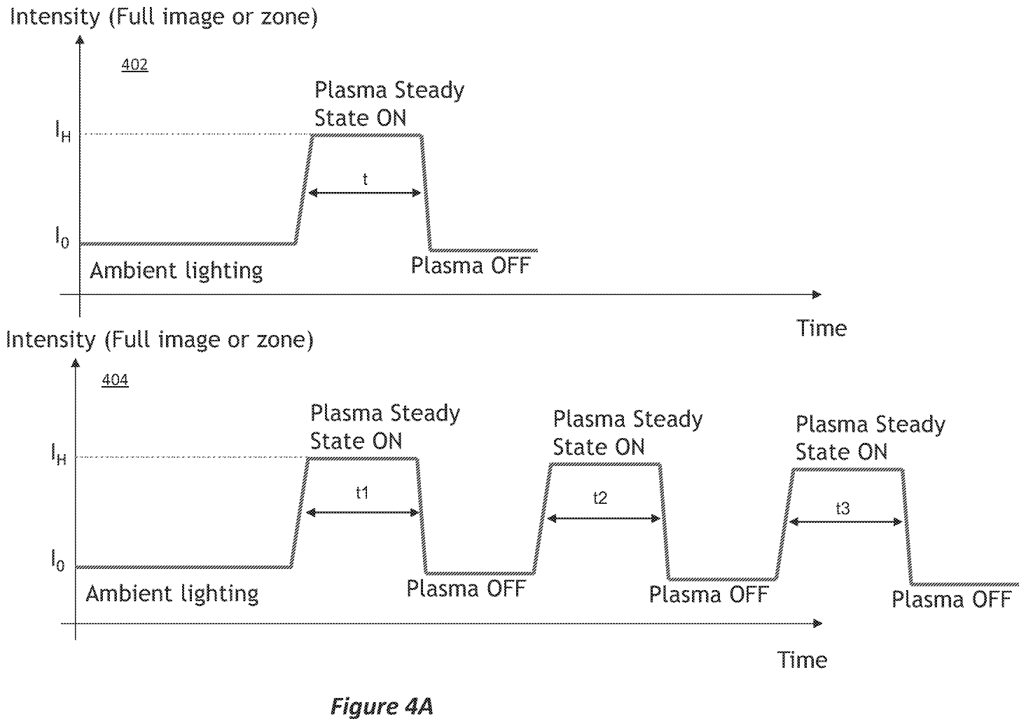

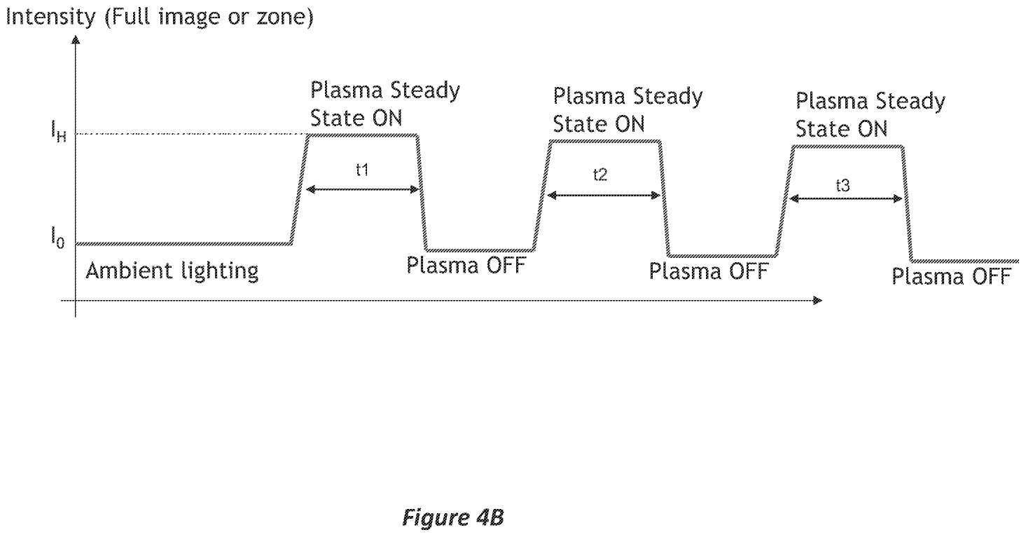

In the context of camera sensors used to analyze plasmas within a process chamber, a camera sensor and associated process logic may be configured to identify various states of the plasma within the process chamber. Examples of discernible states include a plasma off state, a continuous plasma on state, and a pulsed plasma on state. As an example, FIG. 4, discussed below; presents a simple waveform that can identify sensor output associated with these three different plasma states.

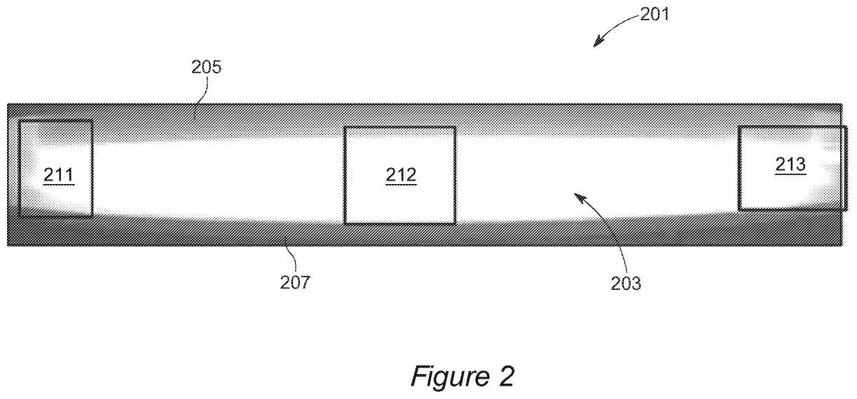

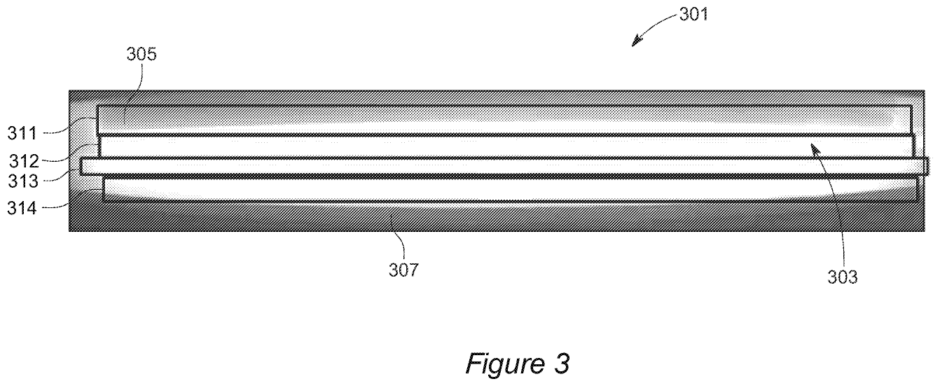

And in some embodiments, a camera sensor may be configured to capture radiation information distributed over an area that can be divided into two or more regions of interest. The radiation information captured from the different regions of interest may be analyzed separately and/or compared. As an example, FIG. 2, which is described further below, illustrates a plasma discharge in a process chamber divided into three regions of interest, 211, 212, and 213. As a further example, FIG. 3, also described below, illustrates a process chamber and associated plasma discharge divided into four regions of interest, 311, 312, 313, and 314.

In some cases, a camera sensor and associated analysis logic are configured to determine one or more characteristics of a plasma or a gas in a region unoccupied by solid structural components of a fabrication tool. An example of such unoccupied regions is a gap between a substrate support and a showerhead or other gas delivery component. Another example of such unoccupied regions is an annular region interior to a chamber wall but outside the domain of a substrate support and/or showerhead.

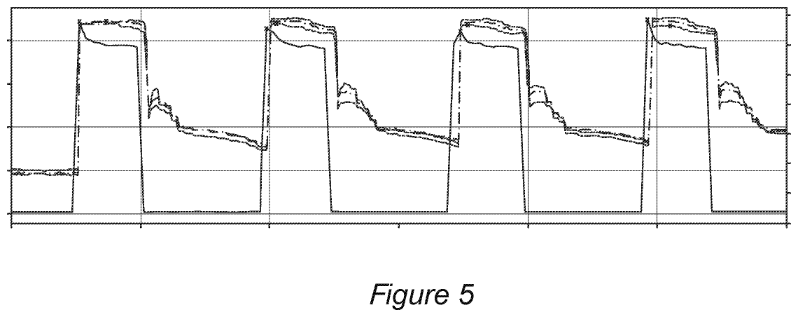

As a further example, a temporally varying plasma discharge in a process chamber can be captured by a camera sensor, and the temporal variations analyzed. For example, a pulsed plasma may have its individual pulses captured and analyzed using a camera sensor as illustrated in, for example, FIG. 5. As described below, the pulses illustrated in FIG. 5 have components in each of four regions of interest. These are regions of interest 311, 312, 313, and 314 shown in FIG. 3.

In various embodiments, a camera sensor captures two-dimensional radiation intensity values over multiple pixels. Analysis logic associated with the camera sensor may be configured to perform image analysis or other analysis that analyzes spatial intensity information and/or presents such information in a way that allows meaningful characterization of a fabrication tool, a process taking place in the fabrication tool, and/or a substrate being processed in a fabrication tool. The camera sensor analysis logic may be configured to receive inputs comprising spatially distributed radiation information, wavelength information, and/or temporal information. The logic may be configured to output images or characterizations of the radiation within a fabrication tool. In some implementations, the logic is configured to analyze the camera sensor data to characterize a condition within a fabrication tool. In the context of a plasma-based process chamber, examples of such characteristics may include spatial distributions of plasma intensity, temporal distributions of plasma intensity, parasitic plasmas, particle formation in the plasma, gas flow patterns in or near a plasma, and conditions of structural features adjacent a plasma.

In various embodiments, a camera sensor is used in conjunction with one or more non-camera sensors that capture information about the fabrication tool and/or conditions within the fabrication tool. Examples of such additional sensors include voltage/current sensors, optical emission sensors, and temperature sensors such as thermocouples, thermistors, pyrometers, bolometers, and semiconductor-based temperature sensors.

In certain embodiments, camera sensor analysis logic is configured to analyze information captured by a camera sensor in conjunction with information captured by one or more other sensors and provide characteristics of conditions within a fabrication tool such as chemical composition characteristics, process gas flow rate characteristics, plasma characteristics, tool component characteristics, and any combination thereof.

In certain embodiments, analysis logic is configured to account for a “baseline” or other prior state representation to which current information captured by a camera sensor is compared. The logic may be configured to identify differences between the current and prior state representations and/or determine from differences a diagnosis of a fabrication tool component, a process control adjustment, or the like. In some embodiments, analysis logic may be configured to use information captured by a camera sensor in conjunction with information about a process and/or a fabrication tool component to determine adjustments to process parameters. Examples of information about the process or fabrication tool include recipe states, setpoints, and timing of operations in the fabrication tool.

To facilitate decision making based on camera images, the analysis logic may be configured to conduct image and/or video analysis, including any of various computer vision techniques. Examples include edge detection, intensity thresholding, etc. In some embodiments, the analysis logic includes a machine learning model and may conduct ongoing learning such as by using deep learning techniques.

### Terminology

Unless specified otherwise herein, all technical and scientific terms used herein have the meanings commonly understood by one of ordinary skill in the art. The terms and explanations provided immediately below are provided to aid in understanding complex concepts and to present particular embodiments. They are not intended to limit the full scope of the disclosure.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of approximately 100 mm, 150 mm, 200 mm, 300 mm, or 450 mm. This detailed description assumes the embodiments are implemented on a wafer. However, the disclosure is not so limited. The work piece may be of various shapes, sizes, and materials. Besides standard semiconductor wafers, other work pieces that may take advantage of the disclosed embodiments include various articles such as compound semiconductor wafers, printed circuit boards, magnetic recording media, magnetic recording sensors, mirrors, optical items (including optical substrates, wafers, and elements), micro-mechanical devices and the like.

Integrated circuits or other electronic devices may be fabricated on a wafer. Examples of such other electronic devices include LEDs, optical displays, tint-able devices such as photochromic and electrochromic devices, micro lens arrays, thin film batteries, and photovoltaic devices.

A “semiconductor device fabrication operation” or “fabrication operation,” as used herein, is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes: and material additive processes, such as deposition processes (e.g., physical vapor deposition, chemical vapor deposition, atomic layer deposition, electrochemical deposition, and electroless deposition). In the context of etch processes, a substrate etch process includes processes that etch a mask layer or, more generally, processes that etch any layer of material previously deposited on and/or otherwise residing on a substrate surface. Such etch process may etch a stack of layers in the substrate.

“Manufacturing equipment” or “fabrication tool” refers to equipment in which a manufacturing process takes place. Manufacturing equipment may include a processing chamber in which the workpiece resides during processing. Typically, when in use, manufacturing equipment performs one or more electronic device fabrication operations. Examples of manufacturing equipment for semiconductor device fabrication include subtractive process reactors and additive process reactors. Examples of subtractive process reactors include dry etch reactors (e.g., chemical and/or physical etch reactors), wet etch reactors, and ashers. Examples of additive process reactors include chemical vapor deposition reactors, and atomic layer deposition reactors, physical vapor deposition reactors, wet chemical deposition reactors, electroless metal deposition cells, and electroplating cells.

In various embodiments, a process reactor or other manufacturing equipment includes a tool for holding a substrate during processing. Such tool is often a pedestal or chuck, and these terms are sometimes used herein as a shorthand for referring to all types of substrate holding or supporting tools that are included in manufacturing equipment.

As used herein and unless otherwise qualified, the term camera sensor is not limited to sensors designed or configured to work with a camera. The term includes other multi-pixel radiation sensors, with or without color or multispectral filters, that can provide sensed information that can provide an image of a radiation distribution within a fabrication tool.

The term “image” refers to a spatial representation of a physical domain including one or more features. An image may be provided in the form of data or signals arranged to represent the physical domain. An image may be produced by a pixelated sensor such as a camera sensor. An image may contain the spatial representation of the physical domain in one dimension, two dimensions, or three dimensions. Multiple images obtained consecutively over time may form a video representation of the physical domain.

A “region of interest” is a bounded region in two-dimensions or three-dimensions within a field of view of one or more camera sensors. In various embodiments, a region of interest includes a region within a fabrication tool. A region of interest may include encompass an area or volume where plasma exists, at least temporarily, within a fabrication tool. In some cases, a boundary of a region of interest has a vertical dimension within a fabrication tool, e.g., along an axis perpendicular to the main flat surface of a wafer support (e.g., pedestal) and/or a chamber showerhead. In some cases, a boundary of a region of interest has a horizontal dimension within a fabrication tool, e.g., along an axis parallel to the main flat surface of a wafer support (e.g., pedestal) and/or a chamber showerhead. In some cases, a boundary of a region of interest has an azimuthal dimension within a fabrication tool, e.g., an angular position along a circumferential portion of a substrate/wafer, showerhead, or pedestal.

Information Collected with a Camera Sensor

Information about conditions within a process chamber, as captured with a camera sensor or pixelated sensor, may include radiation intensity values as a function of position within the process chamber. In some embodiments, the radiation intensity values are provided as an image. In some embodiments, the radiation intensity values are provided as two-dimensional or three-dimensional pixelated values. In other embodiments, the radiation intensity values are provided in only one dimension such as along a slit or interface between components. In some implementations a one-dimensional sensor or array is configured to scan the interior of a process chamber to generate, e.g., a two-dimensional image of a portion of the process chamber interior.

Optionally, the intensity values are also provided as a function of wavelength. In some embodiments, a camera sensor or other pixelated sensor comprises separate detection elements, each configured to capture radiation values at a given location, but with different spectral sensitivity profiles: e.g., in the red, green, and blue regions. Some camera sensors are configured to capture radiation intensity values in discrete wavelength ranges that are sometimes referred to as bins. Such sensors include hyperspectral imagers that capture intensity values in narrow wavelength bins and multispectral imagers that capture intensity values over broader wavelength bins. Optionally, the intensity values are provided as function or time: for example, images may be captured as video frames. In some embodiments, multiple camera sensors provide information from different overlapping or contiguous regions within a fabrication tool.

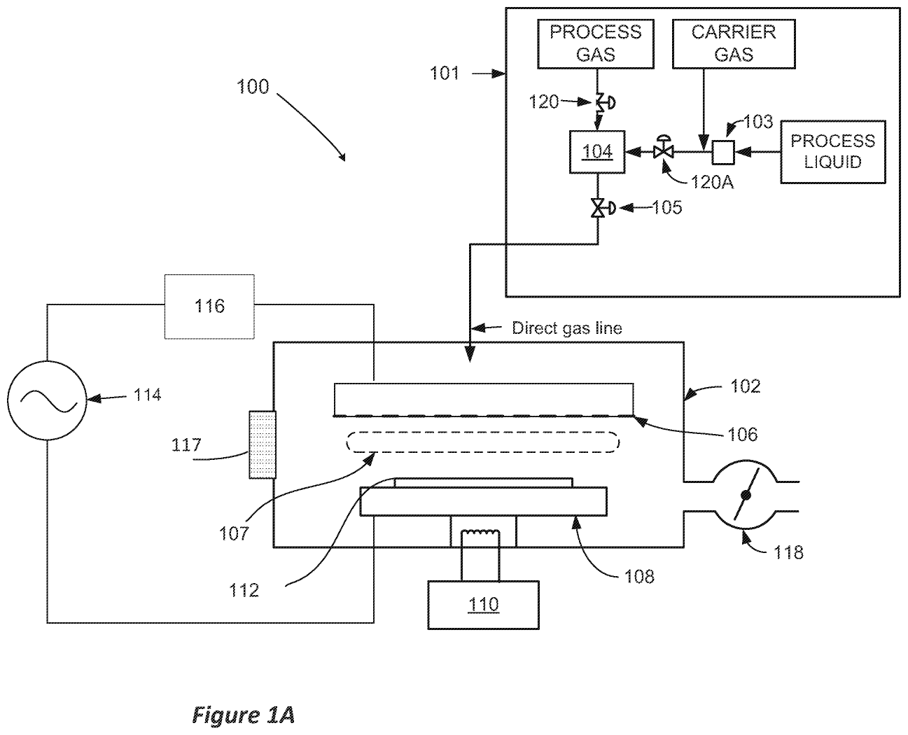

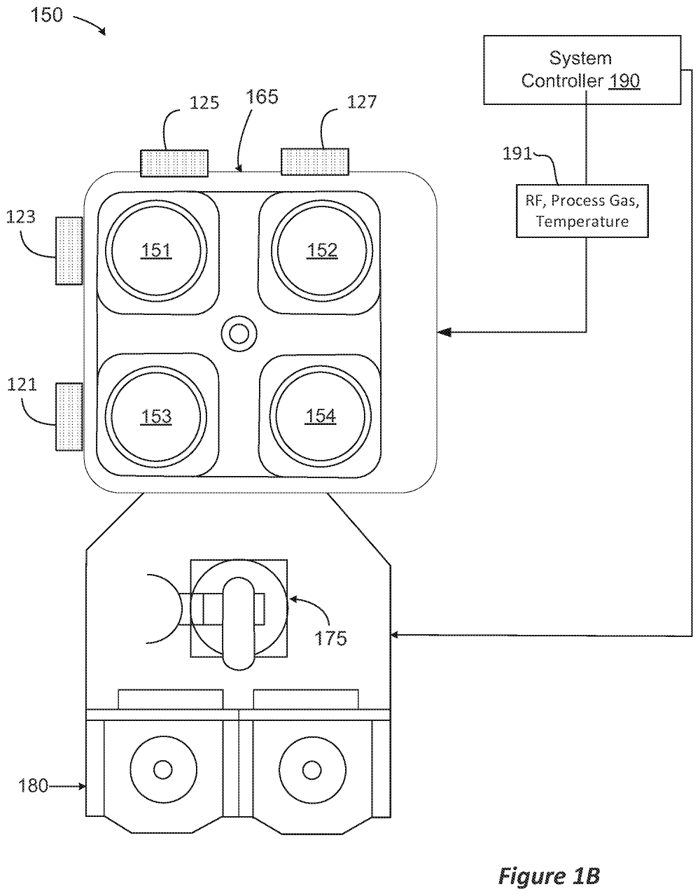

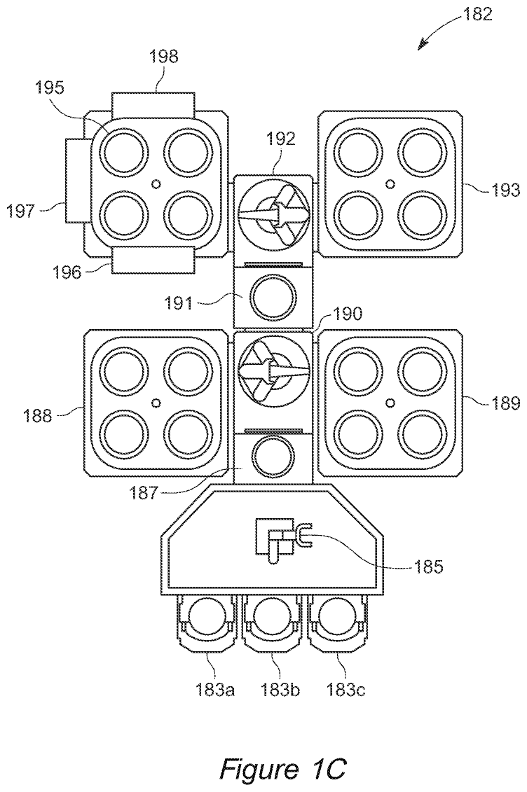

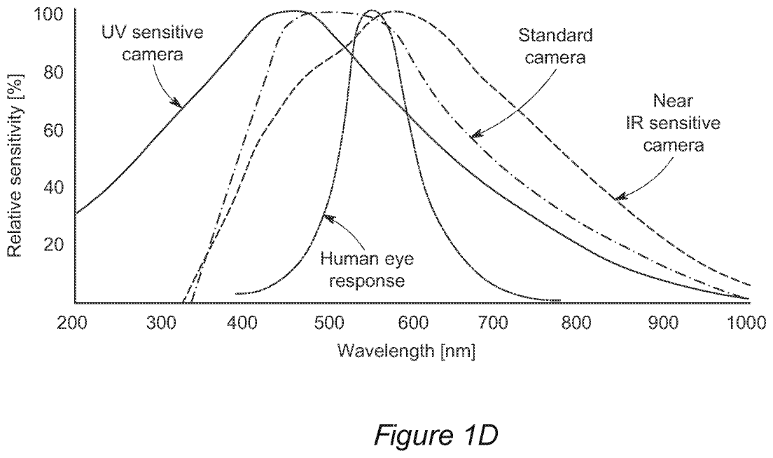

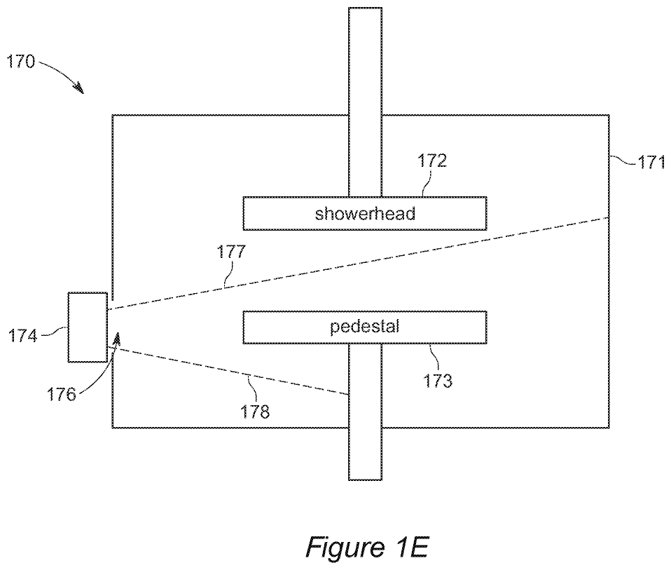

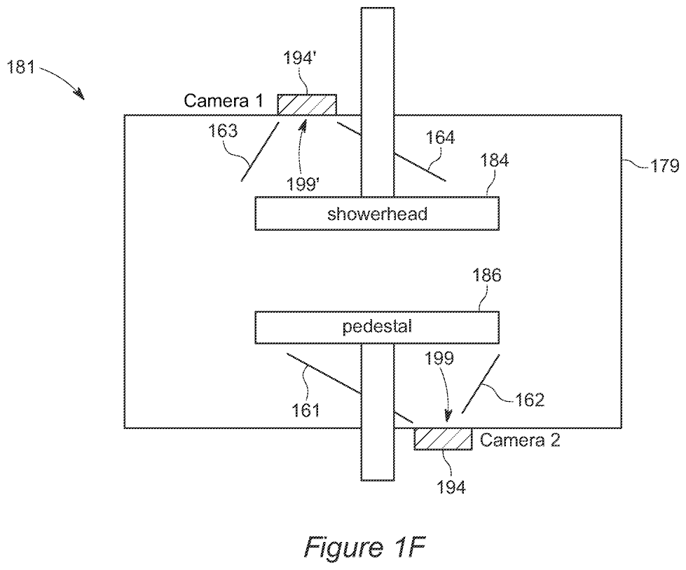

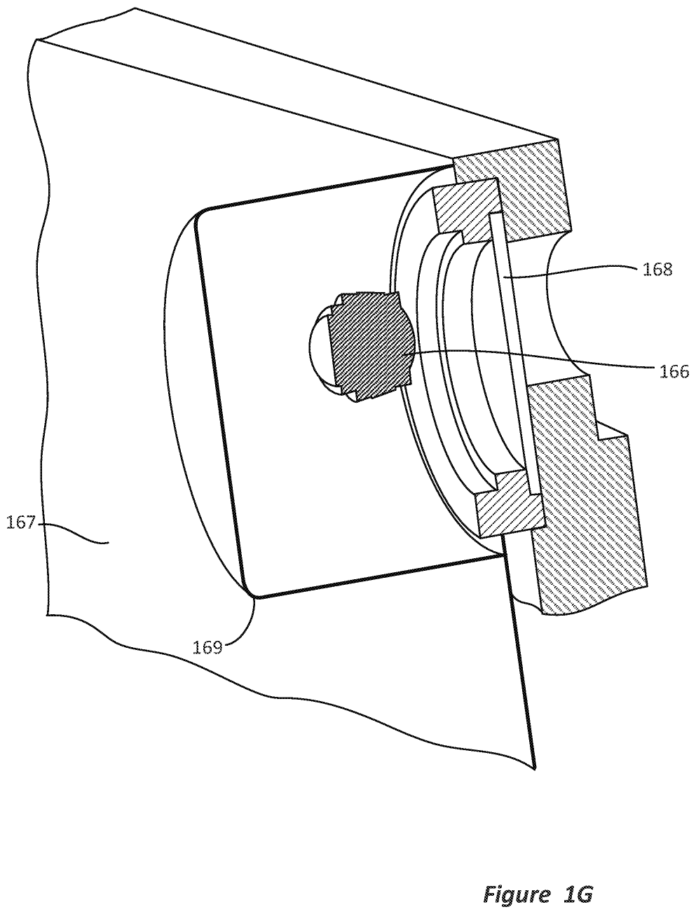

FIG. 1D presents an example of spectral sensitivity ranges for “standard” (visible-sensitive), IR-sensitive, and UV-sensitive sensor elements in a camera sensor or a combination of camera sensors.

### Plasma Characteristics Determined Using a Camera

One or more camera sensors and associated analysis logic may be configured to provide any of various characteristics of a plasma in a fabrication tool. Among the types of plasma characteristics that may be determined are plasma location within a fabrication tool (including the location of a plasma sheath), plasma intensity, plasma electron temperature, plasma potential, chemical species within a plasma, and plasma density.

In some embodiments, logic for analyzing information sensed by a camera sensor is configured to determine and optionally present a location of plasma within a fabrication tool. Such location may be provided with reference to one or more structural components within a fabrication tool. Examples of such components include a substrate, such as a substrate undergoing a fabrication process, a substrate support, a showerhead, and a process chamber wall. In some embodiments, the plasma location is determined in two or three dimensions radially, azimuthally, and/or vertically with respect to a component such as a substrate pedestal, a showerhead, or chamber walls. In some cases, the location of the plasma is provided as geometric coordinates with respect to an origin, which may correspond to a location within or proximate a fabrication tool. In some embodiments, the location of a plasma is determined based on a centroid of a region occupied by the plasma.

In some embodiments, logic for analyzing information sensed by a camera sensor is configured to determine and optionally present a shape or distribution, or a portion of a shape or distribution, of a plasma within a fabrication tool. The shape or distribution of a plasma may be characterized by a boundary of the plasma. The boundary may be determined by, e.g., a spatial intensity magnitude threshold, an intensity gradient, etc. In certain embodiments, analysis logic is configured to use the shape or boundary location of a plasma to identify one or more plasma anomalies within a fabrication tool. In some cases, a plasma is bounded by a plasma sheath adjacent to one or more electrodes. A camera sensor and associated logic may be configured to determine the location and/or shape/distribution of a plasma sheath. In some embodiments, the shape or distribution of a plasma or plasma sheath is identified for a limited range of wavelengths and/or spectral lines, such as lines associated with particular chemical or atomic species.

In some embodiments, logic for analyzing information sensed by a camera sensor is configured to determine and optionally present an electron and/or ion temperature of a plasma at one or more positions within a fabrication tool. The logic may be configured to provide a distribution of electron and/or ion temperatures over a two-dimensional or three-dimensional region within a fabrication tool. In some cases, the logic is configured to determine a plasma's electron and/or ion temperature by employing not only sensed values from a camera sensor but also sensed information from one or more other types of sensors. Examples of such other types of sensors include voltage/current sensors within the fabrication tool, such as voltage/current sensors located on a showerhead, pedestal, or other component. In some cases, such other sensors can provide information about a plasma's electron and/or ion temperature at a particular location on a structural component such as the edge of a showerhead but not in a region between structural components (e.g., in a gap between the showerhead and a pedestal). A camera sensor can capture information in void regions away from structural components and therefore provide a more complete spatial picture of plasma electron and/or ion temperature within a fabrication tool. In some embodiments, the camera sensor used to determine a plasma's electron and/or ion temperature is a multispectral or hyperspectral camera sensor which can obtain the spectrum across many bands (e.g., more than three, more than six, or more than nine) for each pixel in an image.

In some embodiments, image analysis logic is configured to employ a trained computational model to determine a plasma's electron and/or ion temperature by using one or more camera images, alone or in combination with other inputs. Training may employ one or more techniques to identify electron and/or ion temperature as a tag or ground truth to be used in conjunction with associated camera images. Examples of such techniques include laser-based scattering, Doppler-shift/broadening of emission lines, Stark effect/broadening techniques, the Zeeman effect, and the like.

In some embodiments, logic for analyzing information sensed by a camera sensor is configured to determine and optionally present an electrical potential of a plasma at one or more positions within a fabrication tool. The logic may be configured to provide a distribution of plasma potentials over a two-dimensional or three-dimensional region within a fabrication tool. In some embodiments, the analysis logic is configured determine a relative plasma potential (or spatial potential distribution) with respect to a baseline potential. The relative plasma potential is not an absolute plasma potential, and it may be determined with respect to a baseline. For example, the logic may be configured to interpret camera sensed data to determine a compare an electrical potential of a plasma in a “golden” process to sensed information in other runs or process recipes and determine a drift or shift in plasma potential. This may be employed in validation of runs or processes. In certain embodiments, analysis logic may be configured to determine a plasma's potential by using data from a surrogate model (e.g., from 1D, 2D, 3D simulations) and hybrid experimental calibration data (e.g., emissive probes), trained with camera data.

Various other plasma properties may be determined using a combination of camera sensor information and a non-camera sensor information. One example of such property is RF frequency or a drift of RF frequency of a plasma in a fabrication tool. Another example is pulse frequency or pulsing synchronization error of a plasma in a fabrication tool.

In some embodiments, logic for analyzing information sensed by a camera sensor is configured to determine and optionally present a density of a plasma at one or more positions within a fabrication tool. That plasma density includes contributions from electrons, positive ions, and/or negative ions and may be represented in units of cm⁻³. In some embodiments, the camera sensor analysis logic is configured to assess the visibility of one or more structural features within a fabrication tool and to use such visibility to determine plasma density or a spatial distribution or image of plasma density within the fabrication tool. In some cases, features may be more visible in camera images acquired on lower density plasmas than in camera images acquired on higher density plasmas, e.g., due to saturation. In such cases, properties of a camera sensor may be controlled to account for high-density plasmas. In some embodiments employing a multi-station fabrication tool, the structural features are present in a station under consideration (where the plasma density is being determined) or in an adjacent station. The logic may be configured to provide a distribution of plasma densities over a two-dimensional or three-dimensional region within a fabrication tool. In some embodiments, the analysis logic is configured to determine a spatial distribution of plasma density with reference to one or more structural components within a fabrication tool. Examples of such components include a substrate, such as a substrate undergoing a fabrication process, a substrate support, a showerhead, and a process chamber wall. In some cases, a plasma density distribution is provided as geometric coordinates with respect to an origin, which may correspond to a location within or proximate a fabrication tool.

In various embodiments, the camera sensor analysis logic is configured to identify and optionally characterize variations in one or more plasma characteristics over time. Examples of such plasma characteristics include plasma location and/or shape, chemical species in and/or associated with a plasma, plasma potential, plasma electron temperature, and plasma density. Comparing a current plasma condition, as determined from a camera image, to a baseline condition may be employed to detect, for example, anomalies, which may in turn trigger corrections in the process parameters or maintenance after the run completes. The logic may be configured to identify and/or characterize time-based variations in a plasma as a function of position within a fabrication tool. For example, the logic may be configured to characterize time-based variations in different regions of interest in a fabrication tool. In some embodiments, the logic is configured to characterize plasma pulses over a range of time. In some embodiments, the logic is configured to characterize plasma pulses at two or more regions of interest in a fabrication tool.

In some embodiments, logic for analyzing information sensed by a camera sensor is configured to determine the presence of, and optionally the concentration of, one or more chemical species within a fabrication tool. The analysis logic may be configured to determine and optionally present chemical composition information at one or more positions within a fabrication tool. In some cases, the analysis logic is configured to provide images of the composition distribution of one or more chemical species within a fabrication tool. Examples of chemical species that may be characterized by the analysis logic include unexcited or ground state species, excited species (e.g., radicals), and/or ionic species. Composition information, and in some cases, concentrations of components may be determined using spectral distribution of radiation intensity information sensed by the elements of a camera sensor. The intensity information may be provided in Red/Green/Blue bands of a conventional camera sensor or in four or more spectral bands of a multispectral sensor.

In some cases, analysis logic is configured to use spectral details from the camera alone to provide information about chemical composition or plasma intensity. In some cases, analysis logic is configured to use spectral details from the camera in combination with other wavelength specific signals such as those from a point location such as spectroscopy signals (e.g., OES)) to provide information about chemical composition. In some embodiments, a system employs a multi-spectral camera, a hyperspectral camera, a spectrometer, or some combination thereof to capture information from a plasma that associated logic may use to characterize the chemical composition of one or more components in a fabrication tool. In some implementation, a system is configured with one or more wavelength-specific filters configured to pass only radiation associated with one or more chemical or atomic species of interest. Intensity readings in spectral regions for such species may be interpreted to determine the presence or absence of the species and/or their composition(s).

In some cases, a fabrication tool includes one or more multi-spectral or hyperspectral cameras with one or more color filters that target UV light bands common in certain plasma processes. Examples of such bands include bands of about 50 nm or narrower at spectral locations corresponding to electronic emissions of process gases of interest (e.g., a gas normally used in one or more phases of a layer deposition recipe). While some camera sensors can detect UV light, unless color filters are applied at the sub-pixel level (as may be the case with multi-spectral or hyperspectral cameras), such sensors cannot distinguish between different emission lines in the plasma. Analysis logic may be configured to compare the intensities of emissions at a few key wavelengths (where light passes between filtered regions) over time. The logic may be further configured to use such comparison to provide feedback regarding the chemistry and/or gas flow patterns within the plasma. In some implementations, a notch filter and/or a bandpass filter may be implemented using the analysis logic. In such cases, cutoff frequencies of a filter may be utilized to select certain spectrum regions, thereby allowing control over the type of data collected and/or analyzed by a camera system.

In some applications, component gases are flowed individually into a fabrication tool, and wavelength-specific camera images are provided as baseline or calibration images to elucidate chemical composition information from images of plasmas having multiple chemical components. Camera images may be employed to capture flow patterns of various chemical species within a reactor (e.g., from showerhead to pedestal or wafer). In some cases, analysis logic is configured to use flow information to detect incorrect gas flows during process or abnormality of operation. For example, a multi-spectral camera image may indicate the presence of Gas A when Gas B is expected based on known recipes or other parameters. An accidental change in recipe or system failure resulting in flow of Gas A may be captured early and acted upon immediately, and then optionally troubleshooting based on the wafer performance in future processing of the same or subsequent wafers.

### Location and Integration a Camera in a Plasma Fabrication Tool

FIG. 1A shows a fabrication tool denoted as substrate processing apparatus 100. Apparatus 100 may be configured for depositing films on or over a semiconductor substrate utilizing any number of processes. For example, apparatus 100 may be adapted for performing, in particular, plasma-enhanced chemical vapor deposition (PECVD) or plasma-enhanced atomic layer deposition (PEALD). Apparatus 100 includes a camera or camera sensor 117 on a chamber wall. Camera sensor 117 is configured to capture image data from the interior of apparatus 100. Note that while sensor 117 is shown as a single block, it is intended to depict implementations in which one, two, or more camera sensors are located proximate to one another, optionally sharing a single viewport or other window. In some cases, the individual camera sensors within block 117 are trained on different components or fields of vision within a chamber interior. In some cases, the individual camera sensors within block 117 are configured to capture different spectral ranges (e.g., far IR, near IR, visible, UV, etc.).

Processing apparatus 100 of FIG. 1A may employ a single process station 102 of a process chamber with a single substrate holder 108 (e.g., a pedestal) in an interior volume, which may be maintained under vacuum by a vacuum pump 118. A showerhead 106 and a gas delivery system 101, which are fluidically coupled to the process chamber, may permit the delivery of film precursors, for example, as well as carrier and/or purge and/or process gases, secondary reactants, etc.

In FIG. 1A, gas delivery system 101 includes a mixing vessel 104 for blending and/or conditioning process gases for delivery to showerhead 106. One or more mixing vessel inlet valves 120 may control introduction of process gases to mixing vessel 104. Particular reactants may be stored in liquid form prior to vaporization and subsequent delivery to process station 102 of a process chamber. The implementation of FIG. 1A includes a vaporization point 103 for vaporizing liquid reactant to be supplied to mixing vessel 104. In some implementations, vaporization point 103 may include a heated liquid injection module. In some other implementations, vaporization point 103 may include a heated vaporizer. In yet other implementations, vaporization point 103 may be eliminated from the process station. In some implementations, a liquid flow controller upstream of vaporization point 103 may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead (e.g., valves 120, 120A, 105). In the implementation depicted in FIG. 1A, substrate 112 is depicted as located beneath showerhead 106, and is shown resting on a pedestal 108. Showerhead 106 may include any suitable shape and may include any suitable number and arrangement of ports for distributing process gases to substrate 112. In some implementations involving 2 or more stations, gas delivery system 101 includes valves or other flow control structures upstream from the showerhead, which can independently control the flow of process gases and/or reactants to each station so as to permit gas flow to one station while prohibiting gas flow to a second station. Furthermore, gas delivery system 101 may be configured to independently control process gases and/or reactants delivered to each station in a multi-station apparatus such that the gas composition provided to different stations is different: e.g., the partial pressure of a gas component may vary between stations at the same time.

In the implementation of FIG. 1A, gas volume 107 is depicted as being located beneath showerhead 106. In some implementations, pedestal 108 may be raised or lowered to expose substrate 112 to gas volume 107 and/or to vary the size of gas volume 107. The separation between pedestal 108 and showerhead 106 is sometimes referred to as a “gap.” Optionally, pedestal 108 may be lowered and/or raised during portions of the deposition process to modulate process pressure, reactant concentration, etc., within gas volume 107. Showerhead 106 and pedestal 108 are depicted as being electrically coupled to RF signal generator 114 and matching network 116 for coupling power to a plasma generator. Thus, showerhead 106 may function as an electrode for coupling radio frequency power into process station 102. RF signal generator 114 and matching network 116 may be operated at any suitable RF power level, which may operate to form plasma having a desired composition of radical species, ions, and electrons. In addition, RF signal generator 114 may provide RF power having more than one frequency component, such as a low-frequency component (e.g., less than about 2 MHZ) as well as a high frequency component (e.g., greater than about 2 MHZ). In some implementations, plasma ignition and maintenance conditions are controlled with appropriate hardware and/or appropriate machine-readable instructions in a system controller which may provide control instructions via a sequence of input/output control instructions.

In general, any plasma-assisted fabrication tool may be used to implement the disclosed embodiments, including integration of a camera sensor configured to capture images of plasmas and/or plasma-related phenomena. Example deposition apparatuses include, but are not limited to, apparatus from the ALTUS® product family, the VECTOR® product family, and/or the SPEED® product family, the KIYO® product family, the STRIKER R; product family, and the VERSYS® product family, each available from Lam Research Corp., of Fremont, California, or any of a variety of other fabrication tools employing plasma.

For simplicity, processing apparatus 100 is depicted in FIG. 1A as a standalone station (102) of a process chamber for maintaining a low-pressure environment. However, some fabrication tools employ a plurality of process stations such as shown in FIG. 1B, which schematically depicts an implementation of a multi-station fabrication tool 105. Fabrication tool 150 employs a process chamber 165 that includes multiple fabrication process stations, each of which may be used to perform processing operations on a substrate held in a wafer holder, such as pedestal 108 of FIG. 1A, at a particular process station. In the implementation of FIG. 1B, the process chamber 165 is shown as having four process stations 151, 152, 153, and 154. However, in certain other implementations, multi-station processing apparatuses may have more or fewer process stations depending on the implementation and, for instance, the desired level of parallel wafer processing, size/space constraints, cost constraints, etc. FIG. 1B additionally shows substrate handler robot 175, which may operate under the control of system controller 190, configured to move substrates from a wafer cassette (not shown in FIG. 1B) from loading port 180 and into multi-station process chamber 165, and onto one of process stations 151, 152, 153, and 154.

As depicted, process station 153 has an associated camera or camera sensor 121 located and configured to obtain images from within process station 153 and, in some embodiments, from within process chamber 154. Process station 151 has two associated cameras or camera sensors 123 and 124. Camera sensor 123 is located and configured to obtain images from within process station 151 and, in some embodiments, from within process chamber 152. Camera sensor 125 is located and configured to obtain images from within process station 151 and, in some embodiments, from within process chamber 153. Process station 152 has an associated camera or camera sensor 127 located and configured to obtain images from within process station 152 and, in some embodiments, from within process chamber 154. Any one or more of camera sensors 121, 123, 125, and 127 may be optically coupled to the interior of process chamber 165 via view port of other window disposed in the chamber wall. Additionally, while not shown in the Figure, some embodiments have one or more camera sensors adjacent to process station 154.

Fabrication tool 150 includes a system controller 190 configured to control process conditions and hardware states of process tool 150. It may interact with one or more sensors, gas flow subsystems, temperature subsystems, and/or plasma subsystems—collectively represented as block 191—to control process gas flow, thermal conditions, and plasma conditions as appropriate for controlling a fabrication process. System controller 190 and subsystems 191 may act to implement a recipe or other process conditions in the stations of process chamber 165.

In multi-station fabrication tools, an RF signal generator may be coupled to an RF signal distribution unit, which is configured to divide the power of the input signal into, for example, four output signals. Output signals from an RF signal distribution unit may possess similar levels of RF voltage and RF current, which may be conveyed to individual stations of a multi-station fabrication tool.

FIG. 1C provides a top view of an electronic device fabrication system 182 having four quad-station fabrication tools 188, 189, 193, and 195. Each quad-station tool contains four process stations, each configured to hold and process a substrate. At the front end of system 182 are three FOUPs 183a, 183b, and 183c accessible by a front-end wafer handling robot 185, which is configured to transfer wafers between the FOUPs and a load lock 187. A first wafer handler 190 is located and configured to transfer wafers between load lock 187 and quad-station fabrication tools 188 and 189. Wafer handler 190 is also configured to transfer wafers to second load lock 191 which makes wafer available to quad-station fabrication tools 193 and 195 via a second wafer handler 192.

Quad-station tool 195 includes three cameras 196, 197, and 198 disposed around its outer wall. The cameras are shown vertically affixed to three sides of the four-sided chamber of tool 195. The only side without a camera is the side next to the wafer handler 192. While not shown in FIG. 1C, similar camera arrangements can be provided on any one or more of each of the three other quad station chambers in the system. It should be understood that, in some cases, a system controller may be configured to modify a position or orientation of a given camera (e.g., up, down, left, right, etc.).

FIGS. 1E and 1F schematically illustrate fabrication tools with camera sensors oriented to capture images from a horizontally directed and a vertically directed line of sight, respectively. FIG. 1E shows a process chamber 170 having a chamber wall 171, a showerhead 172, and a pedestal 173, all designed and constructed in any manner that is known in the art. FIG. 1E also includes a camera 174 arranged to capture images of the interior of process chamber 170 via a view port (as provided on conventional fabrication tools) or a window 176 designed for camera access (e.g., a 1-10 mm diameter sapphire rod). Camera 174 has a field of view defined by edges 177 and 178. As illustrated camera 174 and window 176 are arranged to allow the camera to capture plasma images including the vertical edge of pedestal 173. Other arrangements permit the camera to capture thermal images of other vertical edges in the process chamber.

FIG. 1F shows a similar process chamber 181 but with a camera having a vertical line of sight to allow capture of plasma images of other features. Specifically, chamber 181 has a chamber wall 179, a showerhead 184, and a pedestal 186, all designed and constructed in any manner that is known in the art. FIG. 1F also includes vertically oriented cameras 194 and 194′ arranged to capture images of the interior of process chamber 181 via view ports or windows 199 and 199′ designed for camera access. Camera 194 has a field of view defined by edges 161 and 162, while camera 194′ has a field of view defined by edges 163 and 164. As illustrated camera 194 and window 199 are arranged to allow the camera to capture plasma images including a stem or lower side of pedestal 186. As illustrated camera 194′ and window 199′ are arranged to allow the camera to capture plasma images including an edge of a stem and/or backside of showerhead 184. Other arrangements permit the camera to capture plasma images of other edges in the process chamber.

A camera sensor is typically disposed outside of a fabrication tool, although in some embodiments, it is integrated with a chamber wall or other component or assembly within the chamber. In certain embodiments, a window specially constructed for a camera sensor is integrated into a chamber wall. In certain embodiments, a camera sensor is optically coupled to an interior of a fabrication tool using an optical access aperture that is provided in or on a chamber wall to allow visual inspection of the tool interior.

FIG. 1G illustrates an arrangement for attaching a camera to the wall of a fabrication tool. The view is from the inside of a chamber, which is shown in cross-section. As shown, a camera 166 attached to a wall of a process chamber 167. Camera 166 is configured and oriented to capture images of the interior of process chamber 167 via a view port 168. Camera 166 is disposed in a protective enclosure 169 also attached process chamber wall 167.

Alternatives to the arrangements shown in FIGS. 1A, 1B, IC, IE, IF, and/or 1G, include (a) cameras on corners of chambers (not necessarily on flat walls) and/or (b) light pipes (rigid or flexible) or optical fibers disposed within the reactor (e.g., between one or more view ports or windows in a chamber wall and one or more locations within a chamber interior). Further, it should be understood that systems employing one, two, or more cameras are not limited to quad-station chambers or even multi-station chambers. In some chamber designs, there may not be a view port or there may be insufficient viewports to accommodate all cameras. In such cases, chamber designs may include a wall region to accommodate one or more camera sensors. In general, there can be any of various combination of a single camera and/or multiple cameras and/or lighting systems that can be placed at different locations, including any of various view ports or other windows.

A camera sensor is typically disposed outside of a fabrication tool, although in some embodiments, it is integrated with a chamber wall or other component or assembly within the chamber. In certain embodiments, a window specially constructed for one or more camera sensors is integrated into a chamber wall. In some cases, a window is constructed to permit a lighting system to shine light on the chamber interior to thereby allow the camera to capture images of illuminated chamber components. As explained, a camera sensor may be optically coupled to an interior of a fabrication tool using an existing view port that is provided in a chamber wall to allow visual inspection of the tool interior.

A view port or other window for allowing a camera sensor to “view” a chamber interior may be made from any of a variety of materials. Examples include UV fused silica, UV fused quartz, sapphire, borosilicate glass, and calcium fluoride. In other embodiments, laminates or composites of multiple materials may be utilized in fabricating the windows. In certain embodiments, a window is substantially transmissive over a spectral range of about 100-6000 nm or about 100-1000 nm. To make such a wide spectral range usefully available to a camera, a commercial sensor may need to be modified by removing one or more wavelength-specific or wavelength range-limiting filters on the sensor as manufactured or sold. In some embodiments, a window may include anti-reflective coating to avoid glare from accompanied illumination in the system described elsewhere herein.

A view port or other window for allowing a camera sensor to view a chamber interior may have any of various sizes and shapes. In certain embodiments, a window has a circular, elliptical, rectangular, or polygonal shape. In some embodiments, a window in a chamber wall is constructed as (or including) an optical element such as a mirror, lens, filter, polarizer, or grating. In some embodiments, a window is integrated with a mirror. Some embodiments further may include optical mirrors or other optical components not integrated with the window but rather located within the chamber to, e.g., enable optical access to regions of the chamber that do not have line-of-sight to a view port or window. In certain embodiments, the window is a cylindrical piece of sapphire. In certain embodiments, the window may be coated with one or more antireflective films.

In some embodiments, optical elements permit indirect optical information to be captured by a camera sensor. “Indirect” optical information may include image information outside a line of sight of a camera sensor. Indirect optical information may be reflected, refracted, scattered or otherwise directed from its source, which is outside a field of view of the sensor, to a position inside the field of view of the sensor. To this end, a fabrication tool may include a mirror or other optical element configured to direct light or other optical information into a camera sensor's field of view. In some cases, the optical element is part of a process chamber that has a non-optical function. For example, an aluminum component such as an aluminum chamber wall may reflect light on the IR region of the electromagnetic spectrum.

View ports have been observed to produce thermal and electrical anomalies. Therefore, eliminating view ports and replacing them with small dimension windows may provide benefits to the fabrication tool processing environment. In certain embodiments, a window has a maximum cross-sectional dimension (e.g., a diameter or diagonal) of about 5 cm or less, or about 5 mm or less.

As illustrated in the figures, in certain embodiments, a fabrication tool or a station in a fabrication tool is outfitted with more than one camera. In some cases, a fabrication tool or station has 3 or more cameras, or 5 or more cameras, or 8 or more cameras, or 10 or more cameras. In some embodiments, a station of a multi-station tool has 1 to 3 camera sensors. In some embodiments, 2, 3, or more camera sensors share a single window or view port.

The individual camera sensors of a multi-sensor tool or station may be positioned and configured to capture different fields of view within the tool or station interior. In some implementations, different cameras are located and oriented to capture images of the tool interior at different angles. In some implementations, different cameras are located and oriented to capture images of the tool interior at different translational offsets. In some cases, multiple cameras oriented in such manner may, for example, be arranged to share a single window or view port. In some embodiments, camera sensor analysis logic is configured to stitch or otherwise combine images from two or more individual camera sensors located and oriented to capture different regions and/or angles within a tool interior.

As indicated, in embodiments employing multi-chamber fabrication tools, one or more camera sensors may be located and oriented to capture information about two or more chambers. This may be convenient when two or more stations are along a line of sight from a view port or other window outfitted with a camera sensor. In some implementations, camera sensor analysis logic is configured to use information about structural features of adjacent stations such as station walls, or showerheads, or pedestals, to provide context or frame of reference for plasma radiation data collected from a different station.

In some embodiments, a camera sensor is directly attached to a wall or window of a fabrication tool. A camera sensor may be affixed to a fabrication tool by various mechanisms such as an adhesive, a bolt or other mechanical fixture, a magnet, etc. In some embodiments, a camera sensor is disposed at a remote location from a fabrication tool. For example, a camera sensor may be optically coupled to a view port via a fiber or other light conduit. Some embodiments allow for a camera to be mounted in a protective enclosure within a fabrication tool interior. In some embodiments, a camera or camera sensor has an associated cooling system or thermal management device or component. Examples of thermal management elements include an insulating material (e.g., rubber gaskets), one or more heat dissipative structures, a flowing liquid heat exchanger, etc.

One or more camera sensors may be arranged to provide a multiplexed processing of images. In some embodiments, a single remote sensor may process optical information (and generate images) from multiple locations (e.g., multiple view ports). For example, a single camera sensor may support multiple view ports. In some embodiments, a fabrication tool employs one camera sensor to capture image data from two more stations of a multi-station chamber. For example, a tool may have a first window on a chamber wall adjacent a first station and a second window on the chamber wall adjacent a second station. The tool may additionally include a first optical fiber or light pipe optically coupling the first window to a camera sensor and a second optical fiber or light pipe optically coupling the second window to the camera sensor. The camera sensor is configured to multiplex signals from the first and second optical fibers or light pipes. In some embodiments, the tool includes an array of light pipes and/or an array of optical fibers for conveying optical signals between a source in the tool and a camera sensor.

Images or video clips from one or more camera sensors may be processed in a multiplexed fashion by image analysis logic running on hardware at any of various locations. In some embodiments, this approach is applied to study states of a fabrication tool or conduct other evaluation outside of real time.

In some embodiments, one or more fabrication tools and associated cameras have local edge computers. An edge computer may be configured to execute programs for processing and/or managing camera sensor data. Examples of such programs include image analysis programs and image/video multiplexing programs. In certain embodiments, an edge computer contains a program for multiplexing image/video data from one or more cameras at a fixed rate. In some cases, an edge computer is configured to execute one thread for multiplexing video/images from multiple camera sensors and execute a different thread for analyzing images and/or video. An edge computer may run separate virtual machines for its various responsibilities associated with camera sensors.

In certain embodiments, an edge computer is provided for a single station, but the computer is configured to multiplex and/or otherwise process data from multiple cameras, some of which may not be located at the single station.

### Characteristics of Cameras for Sensing Plasma Conditions

Camera sensors are characterized by various parameters including the number of pixels, range of wavelengths captured, and the like. In some embodiments, a camera sensor for capturing information about a plasma may be capable of sensing intensity values of electromagnetic radiation at wavelengths including at least portion of the UV spectrum, at least a portion of the visible spectrum, at least a portion of the IR spectrum, or any combination thereof. As an example, a camera sensor may be configured to sense intensity values over range including 100 nm to 1000 nm.

As examples for any embodiments herein, camera sensors may be constructed as charge-coupled devices (CCDs) or CMOS arrays. In certain embodiments, a camera sensor as used herein has at least about 5 megapixels or at least about 12 megapixels. In some embodiments, a camera sensor used herein may have as few as about 2 megapixels.

In some implementations, an image capture device is a line or one-dimensional array of sensors or pixels. Such device may be configured to scan across a two-dimensional field of view: The scan direction may be substantially perpendicular to the axis of the line of sensors. In some embodiments, a one-dimensional image capture device is oriented perpendicular to the wafer or chamber component and optionally configured to scan from one side of the chamber to the other (or within other portion or field of view within the chamber).

In certain embodiments, a camera as used in any of the embodiments herein is configured with a shutter. In some implementations, a camera is configured to capture video data of a plasma in a fabrication tool. In certain embodiments, a camera is configured to capture video information of a plasma in a fabrication tool at a frame rate of about 30 fps-120 fps.

In some cases, a fabrication tool may include a lighting system configured to illuminate all or one or more portions of the too interior. In some implementations, a lighting system is configured to allow a camera to take an illuminated image when the plasma is off (e.g., outside operation or in between pulses). Note that in some cases no lighting system is employed and lighting is used from the plasma itself. In some implementations, a lighting system employs one or more LEDs or other light sources. The light sources may be monochromatic, polychromatic with discrete emission wavelengths, or broad spectrum. The light source may be active continuously, pulsed synchronously with one or more camera shutters, pulsed asynchronously with one or more camera shutters, or pulsed synchronously with other process parameters such as RF generators or gas delivery valves. In other implementations, multiple light sources are employed in different locations within or outside the chamber. These multiple light sources can be energized continuously or sequentially with timing managed to enable structured lighting to be utilized to construct super-resolution images of features within the chamber. In some implementations, one or more notch or bandpass filters are provided in front of a light source to produce effects that can support analysis (e.g., identification of particular chemical species by their emission spectra).

Some fabrication tools include a still image or video display. Such display may be employed to allow process engineers or other staff to view the too interior when a camera sensor or light conduit blocks access to a view port from outside the tool. In some embodiments, a view to a chamber interior is provided via images or video streamed electronically (e.g., using the real-time streaming protocol (RTSP), the real-time messaging protocol (RTMP), low-latency HTTP live streaming (HLS), secure reliable transport (SRT), WebRTC, or the like), optionally to a remote location via a web application. Examples of remote sites include a fab monitoring room or facility, a smart phone, a tablet, and/or a desktop computer system. In some embodiments, communication of the image(s) or video is made via network that includes, as a node, a camera on a process chamber. Such network may be wired or wireless, e.g., a mesh network. In certain embodiments, a network employs a protocol employing WiFi, Bluetooth, cellular, etc.

Other Sensor Types that May be Used in Conjunction with Cameras

In some embodiments, a fabrication tool includes one or more sensors in addition to a camera sensor. Such additional sensor(s) may be configured to sense a plasma or other conditions in situ. Such sensors may include, but are not limited to, mechanical limit sensors, inertial sensors (e.g., accelerometers or gyroscopes), infrared (IR) sensors, acoustic sensors, mass flow sensors, pressure sensors such as the pressure manometers, and temperature sensors such as thermocouples, which may be located in a process gas delivery system, a pedestal, a chuck, etc. Specific examples of additional sensors include current sensors (e.g., VI probes), which may be affixed to one or more structural components such as a showerhead or pedestal, an in situ spectroscopic sensor configured to capture emitted radiation from a wafer or reactor component in the UV, visible, and/or IR spectrum (e.g., an optical emission spectroscopy sensor (OES)), an in situ sensor configured to detect optical absorption characteristics of gases in the process chamber, an in situ optical metrology tool such as a reflectometer.

One example of an additional sensor is a capacitive voltage sensor having a relatively high input impedance. One example of an additional sensor is an inductive current transformer having a relatively low input impedance that occasionally or periodically samples a current conducted from an RF signal generator without bringing about any significant voltage drop. In some embodiments a current or voltage sensor is coupled in series between RF signal generator and a multi-station fabrication tool.

### Camera Image Analysis

Image analysis logic is configured to receive sensed values from one or more camera sensors on a fabrication tool. In certain embodiments, inputs to the image analysis logic include pixel-by-pixel intensity values as a function an observable parameter such as wavelength, time, polarization, or any combination thereof. In certain embodiments, input data from a camera sensor is provided in the form of image data, video data, spectral values, time series data, wafer metrology data and the like. In some embodiments, the input data is filtered by wavelength, polarization, etc. In some embodiments, analysis logic is configured to receive and act on additional input information beyond camera sensor intensity data. Such additional input information may include metadata about the camera sensor and/or associated camera components, substrate metrology information, historical information about the fabrication tool, etc.

The analysis logic may be configured to output one or more properties of plasma in a fabrication tool and/or a classification of a state of the fabrication tool or a component thereof. Some examples of plasma properties were presented above. In some embodiments, the analysis logic is configured as a classifier for diagnostic purposes, or for predictive purposes, or for control purposes. Examples of diagnostic classifications include fault detection and anomalous conditions. Examples of predictive classifications include process or mechanical drift (e.g. a varying shape of a showerhead or other component) and associated predictive maintenance (generated by, e.g., regression analysis). Further examples are provided in PCT/US2021/058550, filed Nov. 9, 2021, which is incorporated herein by reference in its entirety. Examples of control classifications include recommended modifications to apparatus or processes.

Camera sensor analysis logic may comprise any of various types of classifiers or models such as deep neural networks (e.g., convolutional neural networks, autoencoders, UNet, etc.), traditional or classical computer vision methods such as edge detection, image modification (such as blurring, changing contrast), intensity thresholding, color channel thresholding, etc.

Analysis logic may be configured to perform an image processing routine such as a segmentation or other edge finding routine. In certain embodiments, analysis logic is configured to use segmentation or other edge detection method to determine plasma property information relative to a system component. Segmentation can isolate the component. For example, identification of showerhead and detection of plasma properties some distance away from it may employ segmentation. In the field, when mechanical mounting may not always be consistent, segmentation can help minimize errors (as opposed to fixing the (x, y) location for all images/video generated by a fleet of tools).

The logic may employ any of various techniques for edge detection or segmentation. For example, the logic may employ a threshold-based method, a deep learning model, etc. In some embodiments, the edge of a plasma or the boundary of a subregion within a plasma having defined plasma characteristic may be determined using a processing sequence such as the following: (a) data reduction, (b) denoising (e.g. gaussian blur), and (c) edge finding/thresholding (e.g., a Canny sequence of filter).

In some embodiments, image analysis logic is configured to determine a location of a plasma based on, at least partly, a centroid of a region occupied by the plasma. A plasma's centroid may be a geometric centroid determined from a region deemed by analysis logic to be within boundaries of the plasma. In some cases, the centroid is calculated by considering the intensity of radiation within an image of the plasma. This may be implemented by weighting pixels or regions of an image based on, at least, the intensity values of the pixels or regions. A plasma's centroid may also be determined by simply applying an intensity threshold to the pixel or region values, and only considering those pixels or regions having intensity values above the threshold when calculating the centroid.

Analysis and/or control logic may employ a plasma centroid to determine the alignment or tilt of the process chamber, the showerhead, the pedestal, and/or other component. For example, the logic may compare the centroid position of a process chamber under consideration to an expected or baseline centroid position for a properly aligned process chamber or process chamber component. If the centroids do not agree to within a defined tolerance, the logic may flag the current system as being out of alignment.

In some embodiments, image analysis logic is configured to determine a location of a plasma by integrating or summing optical intensity values over a bounded region of interest within a field of view of the first camera sensor. Examples of regions of interest include a gap between a pedestal and showerhead or a subregion of the gap such as shown in the figures.

In some cases, analysis logic is configured to determine a plasma's location based on, at least, a point or boundary of a plasma having a defined spectral characteristic. The defined spectral characteristic may be a region of the EM spectrum associated with a gas or component in the process chamber. The spectral region may be associated with an emission spectrum and/or one or more emission lines of a gas or component in the process chamber. A spectrally limited location of the plasma may be used to identify the composition and/or location of a gas within a process chamber or a station thereof. For example, if gas of a particular composition is to be located only above a showerhead and it is found to be located in the gap between a pedestal and showerhead, the analysis logic may flag the process chamber or the current process as needing inspection or modification.

In certain embodiments, analysis logic is configured to perform streaming data analysis. As view ports are replaced with cameras, engineers will require a “window” to the fabrication tool interior. In certain embodiments, an image or video processing system is configured to provide access to live stream of data which may be accessed through a fabrication tool's computer, local wireless streams to cellphone apps, and other intranet channels accessible via, e.g., a browser. In some embodiments, analysis logic is configured to perform analytics such as component segmentation and classification in real time. As an example, analysis logic may be configured to flag faults such as a stuck pin in a wafer support. The logic may ensure that such issues are addressed before, e.g., processing another wafer.

In certain embodiments, analysis logic is configured to perform fixed frame (image) and/or video analysis. As explained elsewhere herein, the analysis logic may be configured to analyze and interpret where static image or multiple temporal frames depending on the use case.

In certain embodiments, analysis logic is configured to with edge computing capabilities. To minimize network traffic, at least some computation may be performed on an edge node (or multiple edge nodes) and only limited data is transferred to remote computational or memory resources (e.g., remote storage databases). Decisions on control, feedback, warnings, and the like may be based on computing capabilities on the edge nodes.

In certain embodiments, analysis logic is configured to perform feed forward and/or feedback for multiple applications (process control, auto calibrations, hardware adjustments, etc.). In certain embodiments, computational resources are configured to feed results of a camera analysis to a controller of process conditions at a subsequent (downstream) tool. For example, analysis may be conducted on plasma images captured while a wafer is being processed in a single station plasma tool. The results of analysis may be used to control conditions in an adjacent module for additional deposition. As another examples, information on non-uniformity on station 1 can be used to compensate process conditions at station 2, 3 or 4 . . . or in the current or subsequent process steps.

In certain embodiments, analysis logic is configured to perform multiplexing and/or stitching of images. Multiplexing (e.g., multi-threaded processing) may allow a single processor to process images from more than one camera. Multiplexing may allow a single processor to handle images from multiple wavelength ranges. In certain embodiments, multiple cameras are used to generate not only a rich stream of temporal data but also spatial locations from multiple perspectives. While there may be some delays due to switching from camera to camera, for some applications such as CW processes, analysis logic can generate a combined image capturing more than just the field of view of one camera. In some embodiments, analysis logic is configured to reconstruct three-dimensional information by combining additional sensors and cameras (and optionally modeling data).

### Use Cases and Applications

Various applications determine the location of a plasma (or a portion of a plasma having a particular characteristic such as a defined range of plasma potential, density, or electron temperature) within the interior of a fabrication tool. In some implementations, a camera sensor is located and/or oriented to capture information about a plasma in a region unoccupied by a hardware component of a fabrication tool. Examples of such regions include a gap between a showerhead and wafer/pedestal, a region above the showerhead, a region below the pedestal, and a region beyond the circumference of the pedestal but interior to a chamber wall. Some applications determine and/or use spatial variations in plasma properties to assess the condition of a fabrication tool, one or more of its components, and/or process conditions. Certain of these applications involve dividing a field of view (and the associated portion of fabrication tool interior) into one or more regions of interest and characterizing the plasma (or portion of a plasma) in each such region of interest. The field of view may be determined by one camera sensor or multiple camera sensors.

In some implementations, analysis logic is configured to analyze multiple regions of interest within the interior of a fabrication tool. As an example, analysis logic is configured to analyze a gap between a wafer support and a showerhead or other gas delivery component. In some embodiments, the regions of interest are separated from one another along a horizontal axis parallel to a substantially planar surface of a pedestal or showerhead. In some embodiments, the regions of interest are distributed along a vertical axis in the gap and perpendicular to a substantially planar surface of a pedestal or showerhead.

FIG. 2 presents a camera image 201 of a plasma in a gap 203 between a showerhead 205 and a wafer pedestal 207. Image analysis may be performed separately on depicted regions of interest 211, 212, and 213, which are distributed horizontally (or radially) within the gap 203. The distinct radial positions of each region of interest may have a unique value of a plasma property such electron temperature. As examples, the values of the plasma properties at each region of interest may be represented by an average value in the region, a central tendency (e.g., mean or median) in the region, a variance or deviation in the region, etc.

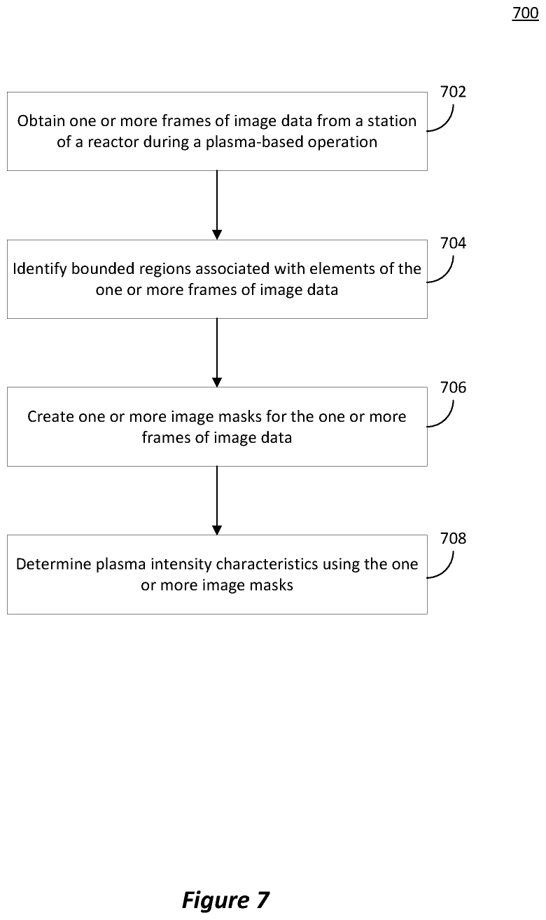

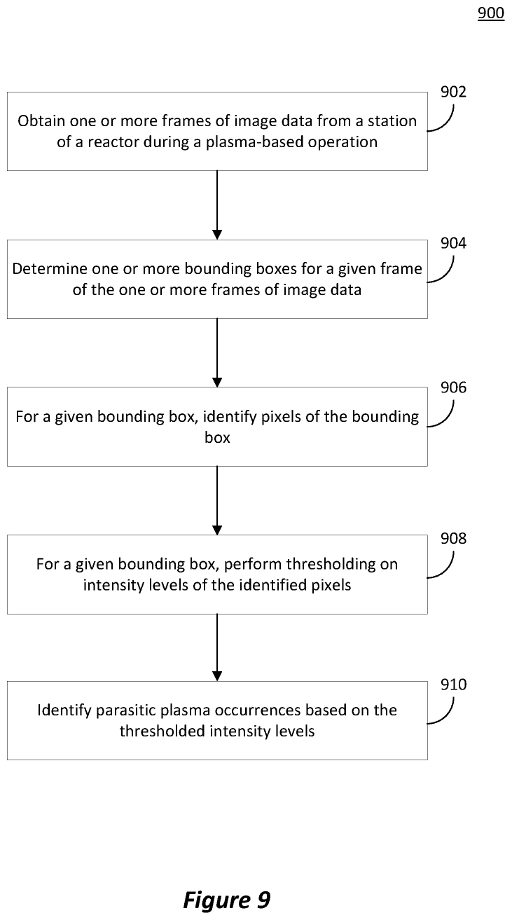

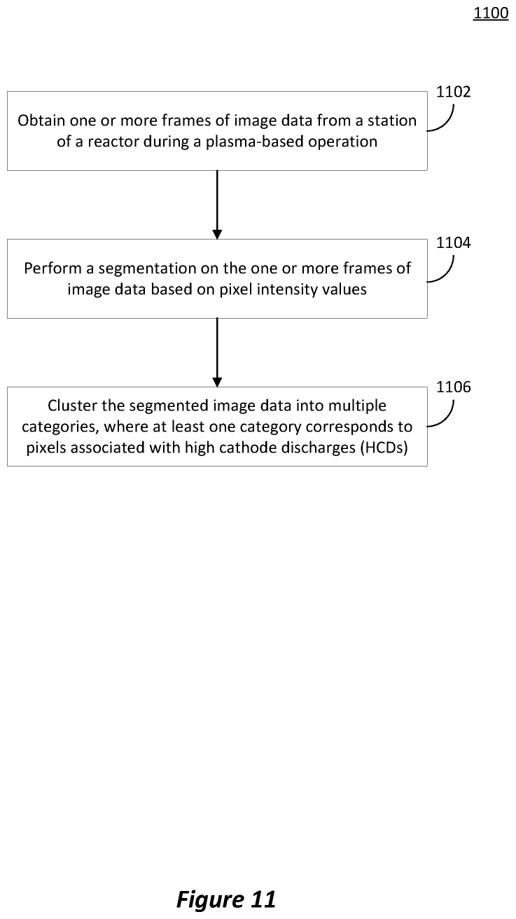

It should be noted that regions of interest may be defined either manually or automatically. For example, manual regions of interest may be indicated using manual (e.g., human) annotation of images. Automatic identification of regions of interest may be identified using a trained machine learning algorithm. For example, such a trained machine learning algorithm may identify contours and/or bounds of elements of interest within an image, such as a showerhead, a pedestal, chamber walls, or the like. A machine learning algorithm may be of any suitable type and/or have any suitable architecture, such as a convolutional neural network, a U-Net, etc. In some cases, a trained machine learning model may be used to generate large training sets for other models. For example, rather than requiring a training set to be manually annotated by a human, which may be time and resource intensive, a trained machine learning model that automatically annotates regions of interest by identifying and annotating bounds of various elements within the image (e.g., the showerhead, the pedestal, chamber walls, etc.) may be used to construct a larger training set than could be constructed relying on manual annotation. The training set may then be used to train one or more other machine learning models, which may include deep neural networks or other suitable architectures. The other machine learning models may be utilized for various purposes, such as characterizing plasma health (e.g., as shown in and described below in connection with FIG. 7), detecting parasitic plasma occurrences (e.g., as shown in and described below in connection with FIG. 9), and/or detecting hollow cathode discharge (HCD) occurrences (e.g., as shown in and described below in connection with FIG. 11). Due to being trained on relatively large training sets (which may be large due to automatic annotation), a given machine learning model may be able to achieve high accuracy, while remaining fast at inference time.

FIG. 3 presents a camera image 301 of a plasma in a gap 303 between a showerhead 305 and a wafer pedestal 307. Image analysis may be performed separately on depicted regions of interest 311, 312, 313, and 314, which are distributed vertically along the gap 303. The distinct vertical positions of each region of interest may have a unique value of a plasma property such as plasma density. As with the image 201 in FIG. 2, the values of the plasma properties at each region of interest may be represented by an average value in the region, a central tendency (e.g., mean or median) in the region, a variance or deviation in the region, etc.

In some implementations, analysis logic is configured to analyze plasma conditions in different regions to make assessments about a tool condition or current operating conditions. For example, plasma property variations within regions of interest may indicate flow patterns of a process gas. If spectral signatures are used, the flow patterns of individual gases within a mixture of gases may be discerned.

In some implementations, analysis logic is configured to determine an abnormal intensity variation within the field of view of camera. Such variations may occur anywhere in a fabrication tool, including in the gap between the pedestal and showerhead, and outside the gap. In some implementations, analysis logic is configured to compare frames temporally to identify possible intensity abnormalities. For example, analysis logic may be configured to analyze frames, e.g., . . . , N−5, N−4, N−3, N−2, N−1, N, N+1, N+2, N+3, N+4, N+5, . . . to determine arcing or other abnormality at a dynamic location within the image. Here N is the image frame of a video where the logic first detects an average intensity variation beyond the normal expectations both when plasma is present or absent.

In some embodiments, the analysis logic is configured to determine whether an arc or parasitic plasma occurs. As an example, the logic may be configured to determine whether a signature of a plasma—e.g., a high intensity value or flash-exists in a region of interest where no plasma or very little plasma is expected such as at radial positions beyond the edge of the showerhead or pedestal, above the showerhead, and/or below the pedestal (backside).

In various applications, analysis logic uses camera sensor images to map regions of high intensity in a plasma to define a boundary or dimension of the plasma such as a diameter of a plasma ring. The analysis logic may employ such boundaries or dimensions to identify spatial shape differences or shifts between stations in a fabrication tool and/or between corresponding fabrication tools in a suite of such tools.

In certain embodiments, the analysis logic receives a time series of images from one or more camera sensors and, based at least in part on these images, determines a current state or a change in condition of a plasma within a fabrication tool. In some cases, analysis logic is configured to compare camera sensor images obtained over a time period that spans processing of two or more substrates, or spans processing of two or more batches of substrates, or spans processing of substrates before and after a fabrication tool is cleaned or serviced. In some cases, analysis logic is configured to compare camera sensor images obtained over a time period that spans processing of a single substrate. In some cases, analysis logic is configured to compare camera sensor images obtained over a time period that spans a single pulse cycle. In some cases, the analysis logic is configured to compare camera images in a manner that provides information about individual plasma pulses over a series of pulses. In order to analyze rapid variation of plasma properties, the camera sensor and associated image capture system may be configured to capture successive images at a rate approaching that of the camera sensor's refresh rate. In some cases, the camera sensor and associated image capture system are configured to capture images at a rate of at least about 100 ms.

For example, a time series of camera images may indicate whether a plasma is off or on, and when it transitions from off to on or on to off. Further, a time series may indicate plasma pulsing. Relatively constant values of a plasma property over time indicates a stable plasma, while relatively variable values of the plasma property over time may indicate an unstable plasma. Temporal variation in plasma characteristics may also indicate instability of the plasma between runs. It may also indicate drifts or shifts of process conditions over time.

FIG. 4A illustrates diagrams of plasma intensity values from a camera sensor or a portion thereof such as in a region of interest for an example PECVD process. Referring to plot 402, initially, a fabrication tool is not operating or is idle, and the only intensity signal from a camera sensor originates from ambient lighting. This signal has a value I₀. At a later time, the intensity value detected by the camera sensor ramps up to a value I_{H} and holds there for a duration of time. The steady value of In indicates that the plasma is on and is stable or not pulsing. After the duration of time at which the plasma remains at I_{H}, the camera sensor value ramps back to I₀, indicating that plasma has turned off. This may be caused by a transition according to defined process sequence or recipe.

Plot 404 illustrates plasma intensity values for a multi-step process. Similar to what is shown in plot 402, during time period 11, the plasma intensity value ramps up to I_{H}, and then back to I₀ after a duration of time. Similar ramps up and down occur during time periods t₂ and t₃. It should be noted that the steps corresponding to t₁, t₂, and t₃ may be the same or different. For example, two steps may correspond to different steps of a multi-step recipe, such as a first step corresponding to nitride, a second step corresponding to oxide, or the like. In some implementations, the time durations associated with different steps may be the same, or may be different. Additionally or alternatively, in some implementations, the steady state plasma intensity value for different steps may be the same, or may be different.

FIG. 4B illustrates a diagram of plasma intensity values from a camera sensor or a portion thereof, such as in a region of interest, for an example ALD process. Similar to what is shown in and described above in connection with FIG. 4A, plasma intensity values may ramp up to a steady state value of In for a duration of time, and then ramp down to I₀ when plasma has turned off. Note that, for ALD processes, plasma on states may be pulsed with the same chemistry (e.g., oxide, nitride, carbide, etc.). Moreover, other steps, not illustrated in FIG. 4B, such as one or more inhibition pulses, may be included after a deposition step. Time durations for an ALD process (e.g., during which the plasma may be on) may be on the order of about 100 milliseconds.

FIG. 5 presents a plot of time-based intensity variations at the four regions of interest 311-314 illustrated in FIG. 3. As illustrated by the periodic rising and falling of the intensity values, the plasma is pulsing. As can be seen, the pulses are not identically experienced at the different regions of interest. For example, at region 314 the plasma intensity undergoes maximal variation from pulse to pulse. In the other three regions, the plasma intensity remains relatively high even when the plasma is essentially off in region 314, thus indicating that the plasma does not fully extinguish between pulses. Further, the plasma intensity decreases in regions 311, 312, and 313 trail (in time) the end of pulse plasma intensity decreases in region 314.

In some applications, camera sensor analysis logic is configured to monitor plasma uniformity. In some implementations, the logic is configured to look at an envelope of the plasma and/or for intensity at specific locations within the gap. If the plasma intensity shows strong variation from region-to-region, it may indicate that the plasma is not uniform. In an example, the plasma intensity is considered at locations close to the showerhead, in the middle of the showerhead-pedestal gap, and at the edge of the wafer or pedestal. Significant variations in intensity between any two of these locations may indicate that the plasma exhibits significant non-uniformity. In some embodiments, the analysis logic is configured to consider the spatial shape differences of the plasma over time or at various locations, which may also indicate non-uniformity. In some embodiments, analysis logic is configured to dynamically adjust its regional focus depending on whether a potentially anomaly is detected while considering relatively large regions of interest. Analysis logic may include subroutines for analyzing larger or smaller (or differently located) regions of interest depending on a current state of the plasma. For example, an initial subroutine could sense for averaged change in intensity for region 311 (for example). If the region 311 behavior is inconsistent, another subroutine could divide it further into more zones to study uniformity variation as a function of, e.g., radial distance from center of the showerhead. Likewise, routines could provide analytic focus at other locations of interest.

While analysis logic can monitor plasma uniformity by considering spatial variations, it can also monitor plasma stability by considering temporal variations at one or more locations or regions within a fabrication tool. Examples of these regions include the gap between the showerhead and pedestal or subregions therein such as the edge of the showerhead, the middle of the gap, and/or the edge of the wafer or pedestal.

In some implementations, analysis logic is configured to compare a current image or collection of images to a baseline or “gold” image obtained for (or representing) a baseline process condition, and/or a baseline fabrication tool state, and/or a baseline tool component state. The baseline may correspond to a known state such as a state in which the process and/or tool are performing acceptably or optimally. If the analysis logic determines that a current image has more than a defined level of deviation from a baseline image, it may flag the tool or operation for further analysis and/or shut down operation of the process or the tool. The deviation may be based on any one or more of the various plasma properties discussed herein. Among the conditions that may cause a significant deviation from the baseline are a tool component is worn or broken (e.g., cracked), gas composition and/or flow characteristics have deviated from specification, a plasma generation component is malfunctioning, etc.

In some applications, camera sensor analysis logic is configured to monitor plasma intensity or other plasma properties over time at one or more locations of tool components. By comparing a plasma property at such location to a baseline or time evolving state, the analysis logic may identify hardware changes such as changes associated with view ports, valves, pumping vents, spindles, robot arms, etc. If the analysis logic detects a plasma property change, the logic may trigger a diagnostic, control, and/or predictive response that may result in maintenance, part replacement, process condition/recipe adjustment, etc.

In some applications, camera sensor analysis logic is configured to compare plasma intensity or other plasma properties from station-to-station in a multi-station fabrication tool. In some implementations, camera sensors or positioned and oriented to capture images of the same hardware components (e.g., vents, valves, spindles, etc.) in each of multiple stations. Analysis logic is configured to compare the sensor images (as viewed when a plasma is present) across the multiple stations. If the analysis logic detects a plasma property variation in any of the stations, the logic may trigger a diagnostic, control, and/or predictive response that may result in a change to the station exhibiting the variation. The change may involve maintenance, part replacement, process condition/recipe adjustment, etc. In some applications, the multi-station fabrication tool employs a common plasma source but splits the delivered power among the different stations in the fabrication tool.

In some applications, camera sensor analysis logic is configured to monitor or characterize process transitions, from step-to-step in a process conducted in a fabrication tool. Camera images of the plasma state during process transitions may allow calibration or matching of other sensors (e.g., non-camera sensors such as VI sensors) or sensor results in the fabrication tool.

In certain embodiments, camera sensor analysis logic is configured to detect plasma abnormalities such as the start of a plasmoid or conditions shortly before a plasmoid occurs. To this end, the analysis logic may be configured to identify flashes or parasitic plasma above or below the showerhead or the pedestal. These conditions may be identified by a change in intensity threshold or shape of the plasma as a function of time and spatial location.

In certain embodiments, camera sensor analysis logic is configured to detect gas-phase nucleation of particles in a plasma, optionally before such particles contact a wafer undergoing processing. Such particles may be evidenced by camera images exhibiting a change in intensity, color, and/or shape of one or more features in the plasma.

Other applications employing plasma characterization by analyzing camera sensor data include determining gap size and identifying equipment leaks.

Various embodiments employ camera and image analysis systems in process control. Some process control applications are described elsewhere herein, such as in the context of feedback and feedforward control. Such process control may control any of various parameters in a fabrication tool. Examples include a process gas composition, a process gas flow characteristic, a pressure within the process chamber, a temperature of one or more components of the process chamber, a plasma power, a plasma frequency, a geometric characteristic of any of the one or more components of the process chamber, and any combination thereof. While many such applications involve controlling processes in real time based on in situ imaging, some applications, particularly feedforward applications, rely on an assessment of an upstream parameter to adjust a future condition in a downstream process or fabrication tool. For example, in some embodiments, certain inhibition-controlled deposition processes rely on multi-chamber operations to get desired results. Information from images of a selective inhibition process (upstream) may be used by analysis logic to set parameters for a downstream deposition process.

In some embodiments, camera sensor data may be utilized to characterize plasma health within a station. For example, plasma health may be characterized by determining plasma intensity values in one or more regions of a station (e.g., between a showerhead and a pedestal, above a showerhead, below a pedestal, etc.). The plasma intensity values may be monitored over time (e.g., over a period of time, such as over multiple months, over a certain number of processes being performed, etc.) to identify changes in plasma intensity values over time. Changes in plasma intensity values over time may be indicative of failures or impending failures of various components of an apparatus.

In some implementations, plasma health may be characterized by identifying different regions of a station within a frame of camera image data. For example, regions corresponding to various components of the station (e.g., a showerhead, a pedestal, chamber walls, etc.) may be identified. Plasma intensity values may then be determined within each identified region. In some implementations, a region may be identified using any suitable computer vision technique, such as edge detection (e.g., using a Canny edge filter, or the like). In some implementations, a region may be identified using a machine learning model trained to perform image segmentation. Such a machine learning model may be a convolutional neural network, or a particular type of convolutional neural network, such as a U-Net.

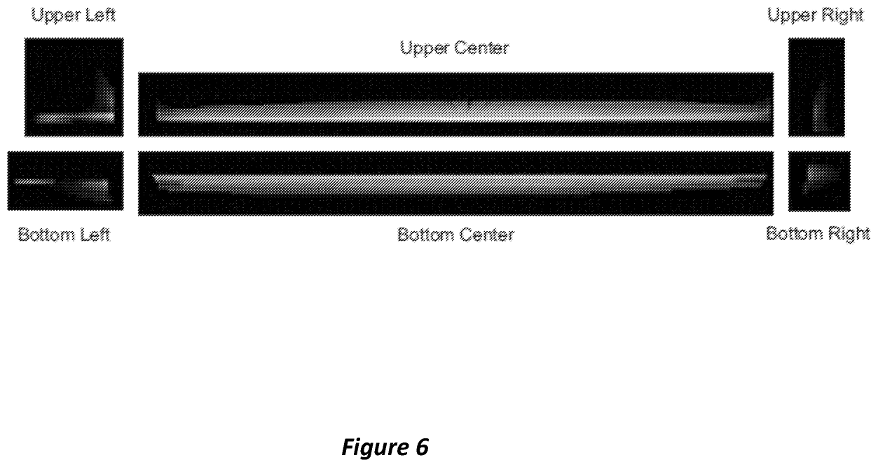

FIG. 6 depicts camera data suitable for determining plasma health within a station. In some implementations, a frame of camera data may be obtained from a camera sensor during performance of a plasma-based operation. In some embodiments, edge detection may be performed on the obtained camera data (Various techniques may be utilized, such as a Canny edge detection algorithm, level set methods, a convolutional neural network, or the like to enable separation of plasma regions. In some embodiments, a contour may be identified that represents a smoothing of the edge detection.

In some implementations, the contour (e.g., a smoothed version of the detected edges of the camera data) may be utilized to create one or more image masks, each corresponding to a different region of the station. For example, a first image mask may correspond to a showerhead, a second image mask may correspond to a pedestal, etc. In some implementations, image masks may be generated for regions corresponding to any suitable combination of: a showerhead region, a pedestal region, an upper left region, a bottom left region, an upper right region, and a lower right region. In some embodiments, image masks corresponding to more than five regions (e.g., eight regions, ten regions, twenty regions, etc.) may be generated. An image mask may be created by determining the bounds of one or more components (e.g., a showerhead, a pedestal, etc.). By way of example, a boundary of a showerhead may be determined by identifying a flat portion of the contour, and left and right bounds of the showerhead. One or more image masks may then be generated based on the boundary of the showerhead (e.g., an image mask corresponding to a region just below the showerhead, an image mask corresponding to a region above and to the left of the showerhead, an image mask corresponding to a region above and to the right of the showerhead, or the like). FIG. 6 illustrates a division of a frame of camera data based on five different regions of the station.

FIG. 7 is a flowchart of an example process 700 for determining plasma health based on camera sensor data. In some implementations, blocks of process 700 may be implemented by a controller or a processor. In some embodiments, a processor may be remote to the plasma-based apparatus, such as that of a server or other remote device. In some implementations, blocks of process 700 may be implemented in an order other than what is shown in FIG. 7. In some embodiments, two or more blocks of process 700 may be executed substantially in parallel. In some embodiments, one or more blocks of process 700 may be omitted.

At 702, process 700 can obtain one or more frames of image data from a station of a reactor during a plasma-based operation (e.g., PECVD, ALD, a plasma-based etch operation, etc.). Examples of camera sensors that may be utilized are shown in and described above in connection with FIGS. 1A-1G.

At 704, process 700 can identify bounded regions associated with elements of the one or more frames of the image data. For example, process 700 can identify a bounded region associated with a showerhead, a bounded region associated with a pedestal, or the like. As described above, the bounded regions may be identified by performing edge detection on the one or more frames of image data (e.g., using a Canny edge detection algorithm, or the like). In some implementations, a contour representing smoothed edges may be generated based on the detected edges. Bounded regions may be identified based on the contour.

At 706, process 700 may create one or more image masks for the one or more frames of image data. The image masks may be created based on the bounded regions identified at 704. In some implementation, each image mask may correspond to a different region of the station of the reactor, such as a region proximate to a showerhead, a region proximate to a pedestal, a region above and to the left of the showerhead, a region above and to the right of the showerhead, a region below and to the left of the pedestal, a region below and to the right of the pedestal, and/or any combination thereof. Note that each image mask may serve to block out portions of the image data other than that associated with a given region of interest.

At 708, process 700 can determine plasma intensity characteristics using the one or more image masks. For example, process 700 can determine plasma intensity values (e.g., as described above) based on pixel intensity values within a given region associated with a particular image mask. Note that, the plasma intensity characteristics may be utilized in any suitable manner to identify anomalous characteristics associated with the station. For example, deviations or trends in the plasma intensity values over time may be identified to determine components in need of repair. As another example, plasma intensity values may be compared to a threshold to determine whether a given plasma intensity value is higher or lower than an acceptable value. In some implementations, plasma intensity characteristics may be used to trigger any suitable maintenance alerts or actions. In some implementations, plasma intensity characteristics may be utilized to modify a process in progress.

In some embodiments, plasma characteristics determined from image data may be used to identify and/or detect parasitic plasma. Parasitic plasma may be plasma that is in an undesired position or region within a station. By way of example, parasitic plasma may be above and to a side (e.g., left or right) of a showerhead, below and/or to a side (e.g., left or right) of a pedestal, or the like. In some implementations, parasitic plasma may be detected by determining bounding boxes on a frame of image data. Bounding boxes may be determined in any suitable manner, such as by providing the image to a trained machine learning model (e.g., a neural network, a feedforward neural network, a convolutional neural network, a U-Net, etc.). Thresholding may then be applied within a given bounding box based on pixel intensity of pixels within the bounding box. Parasitic plasma occurrences may then be identified based on the thresholded pixel values.

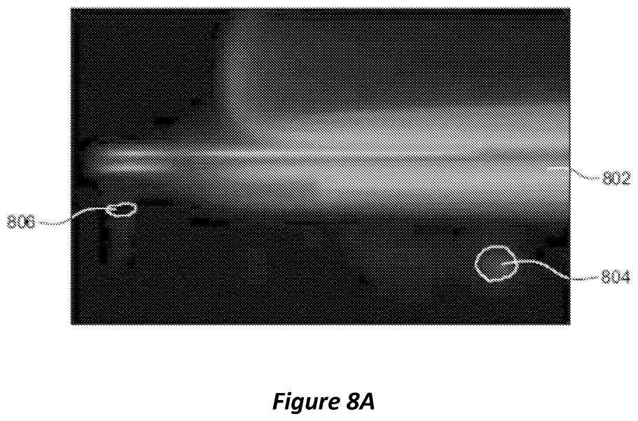

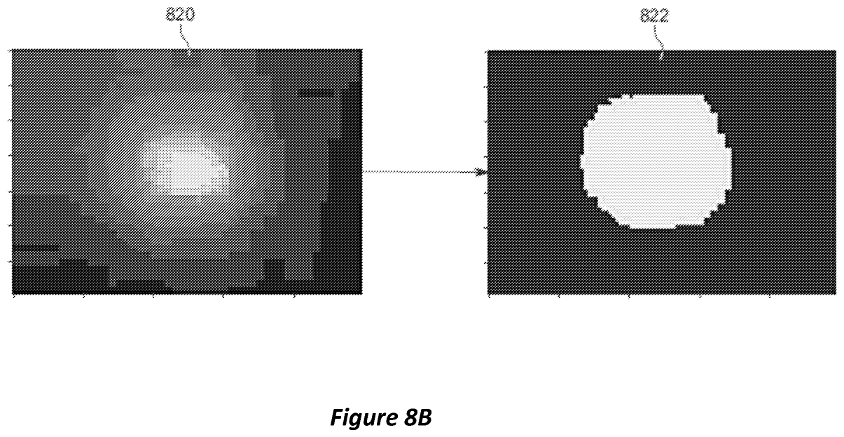

FIG. 8A is an image of a frame of camera data associated with a station during a plasma-based operation. Plasma occurrence 802 represents plasma in an intended region of the station, i.e., in a region between the showerhead and the pedestal. Parasitic plasma occurrences 804 and 806 represent parasitic plasma that is in an undesired region of the station, in particular, below the pedestal. Parasitic plasma occurrences 804 and 806 may be detected using the bounding box and thresholding technique described above, and described below in more detail in connection with FIGS. 8B and 9.

In some embodiments, bounding boxes may be applied to a frame of camera data. Bounding boxes may be determined in any suitable manner, such as by providing the image to a trained machine learning model (e.g., a neural network, a feedforward neural network, a convolutional neural network, a U-Net, etc.). Note that bounding boxes are of different size within different regions of the image, in general, with smaller bounding boxes generated for regions of interest (e.g., with substantial plasma activity).

FIG. 8B illustrates thresholding as applied to a given bounding box. Panel 820 illustrates pixel intensities for a given bounding box. Panel 822 represents the results of thresholding applied to pixel intensity values of panel 820. In other words, pixels associated with pixel intensity values greater than a predetermined threshold may be set to a first value in panel 822, whereas pixels associated with pixel intensity values less than the predetermined threshold may be set to a second value less than the first value in panel 822. It should be noted that, in some implementations, segmentation may be performed using a combination of thresholding and a deep neural network model.

FIG. 9 is a flowchart of an example process 900 for detecting parasitic plasma occurrences in accordance with some embodiments. In some implementations, blocks of process 900 may be executed by a controller or a processor. In some embodiments, the controller or the processor may be remote from the apparatus for performing plasma-based operations, such as a remote server or other remote device. In some embodiments, blocks of process 900 may be executed in an order other than what is shown in FIG. 9. In some implementations, two or more blocks of process 900 may be executed substantially in parallel. In some implementations, one or more blocks of process 900 may be omitted.

Process 900 can begin at 902 by obtaining one or more frames of image data from a station of a reactor during a plasma-based operation (e.g., PECVD, ALD, a plasma-based etch operation, etc.). Examples of camera sensors that may be utilized are shown in and described above in connection with FIGS. 1A-1G.

At 904, process 900 can determine one or more bounding boxes for a given frame of the one or more frames of the image data. Bounding boxes may be determined in any suitable manner, such as by providing the image to a trained machine learning model (e.g., a neural network, a feedforward neural network, a convolutional neural network, a U-Net, etc.).

At 906, for a given bounding box, process 900 may identify pixels of the bounding box. At 908, process 900 may perform thresholding on the identified pixels based on the pixel intensity values. For example, process 900 may set pixels with a pixel intensity value greater than a predetermined threshold to a first value, and may set pixels with a pixel intensity value less than the predetermined threshold to a second value. The second value may be less than the first value. It should be noted that, in some implementations, block 908 may be omitted. For example, in some such implementations, segmentation may be performed using a trained machine learning model, such as a trained deep neural network or the like without performing thresholding. In some embodiments, a trained machine learning model may be used in conjunction with thresholding to perform segmentation.

At 910, process 900 may identify and/or detect parasitic plasma occurrences based at least in part on the thresholded pixel intensity value. For example, process 900 may determine contours that correspond to a cluster of pixels having the first value (e.g., associated with pixels that had intensity values greater than the predetermined threshold as described above at block 908). Note that, in some embodiments, bounding boxes associated with particular regions may be considered when detecting parasitic plasma occurrences. For example, bounding boxes associated with regions other than a region between the showerhead and the pedestal may be considered. In some implementations, clusters of pixels having a contour that does not intersect (or intersects to a minimal degree) with other edges may be considered parasitic plasma occurrences. In some embodiments, a cluster of pixels having the first value may then be considered a parasitic plasma occurrence.

It should be noted that, using the techniques shown in and described above in connection with FIGS. 8A, 8B, and 9, multiple instances of parasitic plasma may be detected within a single frame. Additionally or alternatively, in some implementations, a temporal evolution of parasitic plasma occurrences may be identified, e.g., by evaluating sizes and/or positions of detected parasitic plasma clusters over time.

In some implementations, image data may be utilized to detect and/or identify hollow cathode discharges (HCDs). HCDs may occur in a gap between the showerhead and the pedestal, and may negatively affect wafer processing. In some implementations, HCDs may be detected by segmenting a frame of image data, for example, based on pixel intensity values. In some embodiments, the frame of image data may be a grayscale version of the original captured image data. In some implementations, segmentation may be performed using a transform, such as a top-hat transform, a watershed transform, or the like. Additionally or alternatively, in some implementations, segmentation may be performed using a convolutional neural network, a U-Net, and/or any other suitable trained machine learning model. Based on the segmented image data, pixels of the image may be classified as belonging to a particular category of a group of categories. The group of categories may include background, main plasma (e.g., desired or intended plasma), and HCD. Classification may be performed using a clustering algorithm, such as K-means clustering. HCDs may then be identified based on the assigned classifications or categories.

It should be noted that, in some implementations, techniques for detecting HCDs may be tested and/or refined using simulated HCD occurrences, e.g., because real image data showing actual HCDs may be relatively limited. In such cases, HCDs may be simulated using mathematical shapes and/or functions to configure one or more parameters, where the parameters may include width, height, and/or relative intensity.

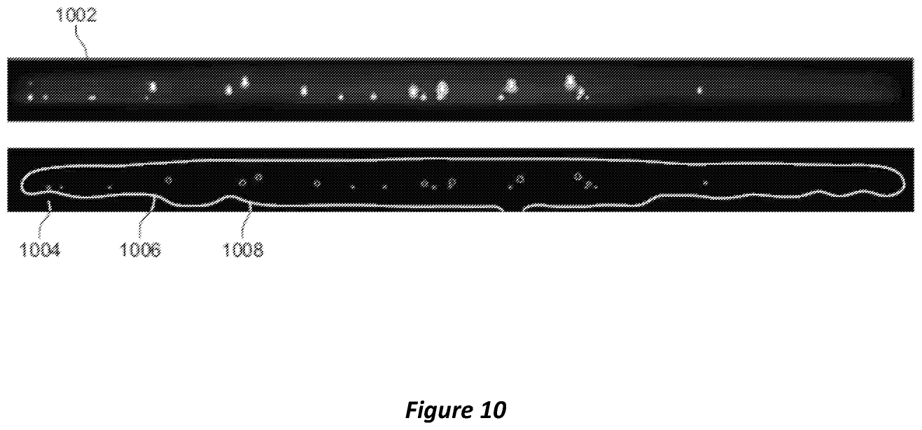

FIG. 10 shows images representing an HCD detection technique in accordance with some implementations. Panel 1002 is a portion of acquired image data corresponding to a region between a showerhead and a pedestal. Panel 1004 represents processed image data of the image data shown in panel 1002. In particular, contour 1006 corresponds to an identified contour of plasma, and circles within contour 1006 (e.g., circle 1008) represents detected HCD occurrences.

FIG. 11 is a flowchart of an example process 1100 for detecting HCD occurrences in accordance with some implementations. In some implementations, blocks of process 1100 may be executed by a controller or a processor. In some embodiments, the controller or the processor may be remote from the apparatus for performing plasma-based operations, such as a remote server or other remote device. In some embodiments, blocks of process 1100 may be executed in an order other than what is shown in FIG. 11. In some implementations, two or more blocks of process 1100 may be executed substantially in parallel. In some implementations, one or more blocks of process 1100 may be omitted.

Process 1100 can begin at 1102 by obtaining one or more frames of image data from a station of a reactor during a plasma-based operation (e.g., PECVD, ALD, a plasma-based etch operation, etc.). Examples of camera sensors that may be utilized are shown in and described above in connection with FIGS. 1A-1G.

At 1104, process 1100 can perform segmentation on the one or more frames of image data based on pixel intensity values. For example, segmentation may be performed using an image transform technique, such as a top hot transform, a watershed transform, or the like. As another example, segmentation may be performed using a trained machine learning model, which may be a convolutional neural network, a U-Net, etc.

At 1106, process 1100 may cluster the segmented image data into multiple categories, where at least one category corresponds to pixels associated with HCDs. In some implementations, the multiple categories may include background image data, normal or intended plasma, and HCDs. In some embodiments, clustering may be performed using a clustering algorithm, such as K-means clustering.

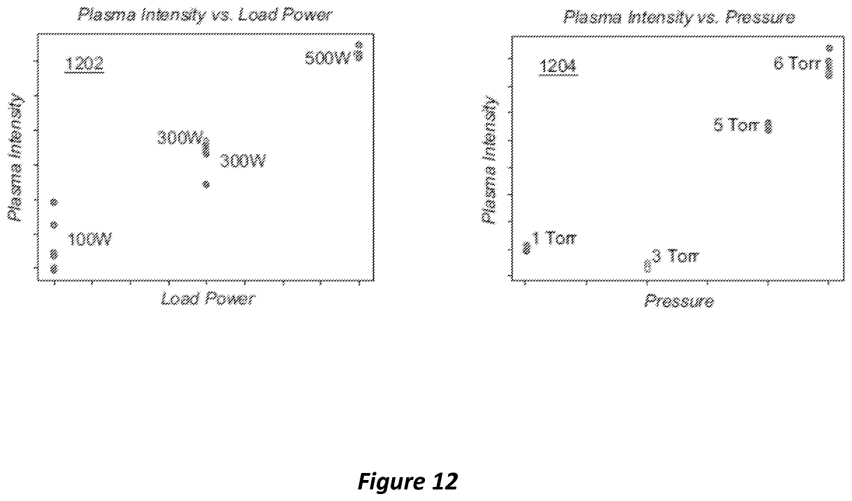

The techniques described herein for determining plasma characteristics based on image data may be used to show relationships between plasma intensity and other physical system parameters. For example, plasma intensity may be related to load power and/or between plasma intensity and chamber pressure. For example, as shown in panel 1202 of FIG. 12, there may be clear clusters of plasma intensity as a function of load power (in Watts). As another example, as shown in panel 1204 of FIG. 12, there may be clear clusters of plasma intensity as a function of chamber pressure. However, it should be understood that load power and chamber pressure are merely exemplary, and plasma intensity may be related to any number of other physical system parameters.

### Sensor Analysis Logic

Systems including fabrication tools as described herein may include logic for characterizing a plasma in a fabrication tool. The analysis logic may be configured to receive signals from a camera sensor by, e.g., analog and/or digital input connections.

The analysis logic may be designed and implemented in any of various ways. For example, the logic can be implemented in hardware and/or software. Examples are presented in the controller section herein. Hardware-implemented control logic may be provided in any of a variety of forms, including hard coded logic in digital signal processors, application-specific integrated circuits, and other devices that have algorithms implemented as hardware. Analysis logic may also be implemented as software or firmware instructions configured to be executed on a general-purpose processor. System control software may be provided by “programming” in a computer readable programming language.

The computer program code for controlling processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

Integrated circuits used in logic may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated in the form of various individual settings (or program files), defining operational parameters for carrying out a particular analysis or image analysis application.

In some implementations, the image analysis logic is resident (and executes) on a computational resource on or closely associated with a fabrication tool from which camera images are captured. In some implementations, the image analysis logic is remote from a fabrication tool from which camera images are captured. For example, the analysis logic may be executable on cloud-based resources.

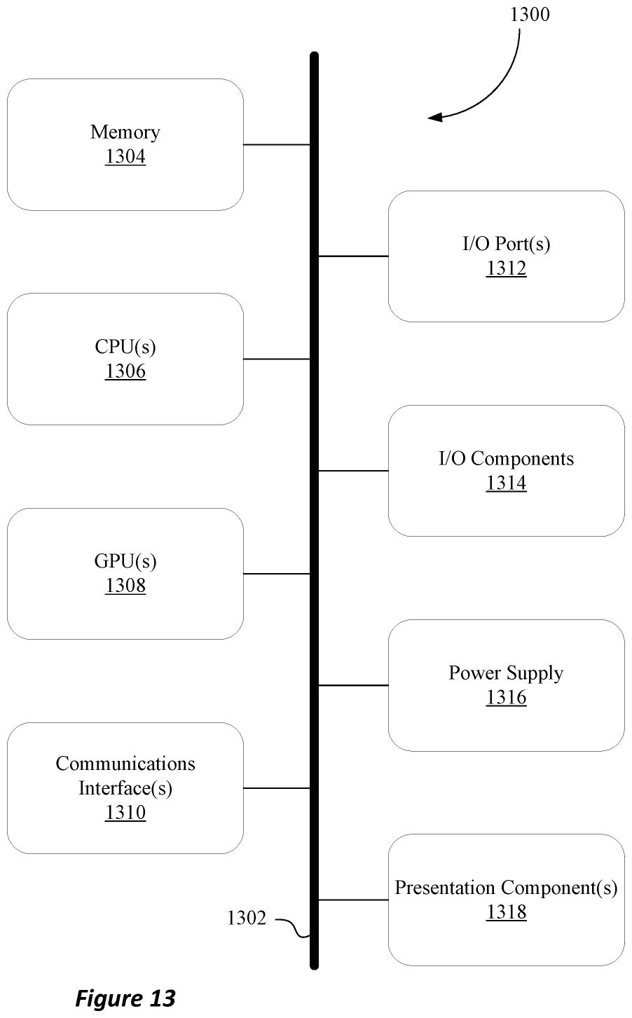

FIG. 13 is a block diagram of an example of the computing device 1300 suitable for use in implementing some embodiments of the present disclosure. For example, device 1300 may be suitable for implementing some or all functions of image analysis logic disclosed herein.

Computing device 1300 may include a bus 1302 that directly or indirectly couples the following devices: memory 1304, one or more central processing units (CPUs) 1306, one or more graphics processing units (GPUs) 1308, a communication interface 1310, input/output (I/O) ports 1312, input/output components 1314, a power supply 1316, and one or more presentation components 1318 (e.g., display(s)). In addition to CPU 1306 and GPU 1308, computing device 1300 may include additional logic devices that are not shown in FIG. 13, such as but not limited to an image signal processor (ISP), a digital signal processor (DSP), an ASIC, an FPGA, or the like.

Although the various blocks of FIG. 13 are shown as connected via the bus 1302 with lines, this is not intended to be limiting and is for clarity only. For example, in some embodiments, a presentation component 1318, such as a display device, may be considered an I/O component 1314 (e.g., if the display is a touch screen). As another example, CPUs 1306 and/or GPUs 1308 may include memory (e.g., the memory 1304 may be representative of a storage device in addition to the memory of the GPUs 1308, the CPUs 1306, and/or other components). In other words, the computing device of FIG. 13 is merely illustrative. Distinction is not made between such categories as “workstation,” “server,” “laptop,” “desktop.” “tablet,” “client device,” “mobile device,” “hand-held device.” “electronic control unit (ECU),” “virtual reality system,” and/or other device or system types, as all are contemplated within the scope of the computing device of FIG. 13.

Bus 1302 may represent one or more busses, such as an address bus, a data bus, a control bus, or a combination thereof. The bus 1302 may include one or more bus types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus.

Memory 1304 may include any of a variety of computer-readable media. The computer-readable media may be any available media that can be accessed by the computing device 1300. The computer-readable media may include both volatile and nonvolatile media, and removable and non-removable media. By way of example, and not limitation, the computer-readable media may comprise computer-storage media and/or communication media.

The computer-storage media may include both volatile and nonvolatile media and/or removable and non-removable media implemented in any method or technology for storage of information such as computer-readable instructions, data structures, program modules, and/or other data types. For example, memory 1304 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 1300. As used herein, computer storage media does not comprise signals per se.

The communication media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the communication media may include wired media such as a wired network or direct-wired connection, and wireless media such as acoustic, RF, infrared and other wireless media. Combinations of any of the above should also be included within the scope of computer-readable media.

CPU(s) 1306 may be configured to execute the computer-readable instructions to control one or more components of the computing device 1300 to perform one or more of the methods and/or processes described herein. CPU(s) 1306 may each include one or more cores (e.g., one, two, four, eight, twenty-eight, seventy-two, etc.) that are capable of handling a multitude of software threads simultaneously. CPU(s) 1306 may include any type of processor and may include different types of processors depending on the type of computing device 1300 implemented (e.g., processors with fewer cores for mobile devices and processors with more cores for servers). For example, depending on the type of computing device 1300, the processor may be an ARM processor implemented using Reduced Instruction Set Computing (RISC) or an x86 processor implemented using Complex Instruction Set Computing (CISC). Computing device 1300 may include one or more CPUs 1306 in addition to one or more microprocessors or supplementary co-processors, such as math co-processors.

GPU(s) 1308 may be used by computing device 1300 to render graphics (e.g., 3D graphics). GPU(s) 1308 may include many (e.g., tens, hundreds, or thousands) of cores that are capable of handling many software threads simultaneously. GPU(s) 1308 may generate pixel data for output images in response to rendering commands (e.g., rendering commands from CPU(s) 1306 received via a host interface). GPU(s) 1308 may include graphics memory, such as display memory, for storing pixel data. The display memory may be included as part of memory 1304. GPU(s) 1308 may include two or more GPUs operating in parallel (e.g., via a link). When combined, each GPU 1308 can generate pixel data for different portions of an output image or for different output images (e.g., a first GPU for a first image and a second GPU for a second image). Each GPU can include its own memory or can share memory with other GPUs.

In examples where the computing device 1300 does not include the GPU(s) 1308, the CPU(s) 1306 may be used to render graphics.

Communication interface 1310 may include one or more receivers, transmitters, and/or transceivers that enable computing device 1300 to communicate with other computing devices via an electronic communication network, included wired and/or wireless communications. Communication interface 1310 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet), low-power wide-area networks (e.g., LoRaWAN, SigFox, etc.), and/or the internet.

I/O ports 1312 may enable the computing device 1300 to be logically coupled to other devices including I/O components 1314, presentation component(s) 1318, and/or other components, some of which may be built in to (e.g., integrated in) computing device 1300. Illustrative I/O components 1314 include a microphone, mouse, key board, joystick, track pad, satellite dish, scanner, printer, wireless device, etc. I/O components 1314 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of computing device 1300. Computing device 1300 may be include depth cameras, such as stereoscopic camera systems, infrared camera systems, RGB camera systems, touchscreen technology, and combinations of these, for gesture detection and recognition. Additionally, computing device 1300 may include accelerometers or gyroscopes (e.g., as part of an inertia measurement unit (IMU)) that enable detection of motion. In some examples, the output of the accelerometers or gyroscopes may be used by computing device 1300 to render immersive augmented reality or virtual reality.

Power supply 1316 may include a hard-wired power supply, a battery power supply, or a combination thereof. Power supply 1316 may provide power to computing device 1300 to enable the components of computing device 1300 to operate.

Presentation component(s) 1318 may include a display (e.g., a monitor, a touch screen, a television screen, a heads-up-display (HUD), other display types, or a combination thereof), speakers, and/or other presentation components. Presentation component(s) 1318 may receive data from other components (e.g., GPU(s) 1308, CPU(s) 1306, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

### Controller Embodiments

In some implementations, a “controller” is part of a system containing a camera sensor as described herein. Such systems include a fabrication tool with a camera sensor. The system may optionally additionally be integrated with electronics for controlling their operation before, during, and after processing of a substrate. The controller may be implemented with or coupled to analysis logic as described above. A controller may be implemented as logic such as electronics having one or more integrated circuits, memory devices, and/or software that receive instructions, issue instructions, control operation, and/or enable sensing operations.

A controller may be configured to control or cause control of various components or subparts of the system or systems. The controller, depending on the processing requirements and/or the type of system, may be programmed to control any of the processes that may be used by a fabrication tool during a fabrication operation, including adjusting or maintaining the delivery of processing gases, temperature settings (e.g., heating and/or cooling) including substrate temperature and chamber wall temperature, pressure settings including vacuum settings, plasma settings, RF matching circuit settings, and substrate positional and operation settings, including substrate transfers into and out of a fabrication tool and/or load lock. Process gas parameters include the process gas composition, flow rate, temperature, and/or pressure. Of particular relevance to the disclosed embodiments, controller parameters may relate to plasma generator power, pulse rate, and/or RF frequency.

Process parameters under the control of a controller may be provided in the form of a recipe and may be entered utilizing a user interface. Signals for monitoring the process may be provided by analog and/or digital input connections of the system controller. The signals for controlling the process are output on the analog and digital output connections of the deposition apparatus.

In one example, the instructions for bringing about ignition or maintenance of a plasma are provided in the form of a process recipe. Relevant process recipes may be sequentially arranged, so that at least some instructions for the process can be executed concurrently. In some implementations, instructions for setting one or more plasma parameters may be included in a recipe preceding a plasma ignition process. For example, a first recipe may include instructions for a first time delay, instructions for setting a flow rate of an inert gas (e.g., helium) and/or a reactant gas, and instructions for setting a plasma generator to a first power set point. A second, subsequent recipe may include instructions for a second time delay and instructions for enabling the plasma generator to supply power under a defined set of parameters. A third recipe may include instructions for a third time delay and instructions for disabling the plasma generator. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example. As explained, plasma may be pulsed.

In some embodiments, a controller is configured to control and/or manage the operations of a RF signal generator. In certain implementations, a controller is configured to determine upper and/or lower thresholds for RF signal power to be delivered to a fabrication tool, determining actual (such as real-time) levels of RF signal power delivered to integrated circuit fabrication chamber, RF signal power activation/deactivation times, RF signal on/off duration, duty cycle, operating frequency, and so forth.

As further examples, a controller may be configured to control the timing of various operations, mixing of gases, the pressure in a fabrication tool, the temperature in a fabrication tool, the temperature of a substrate or pedestal, the position of a pedestal, chuck and/or susceptor, and a number of cycles performed on one or more substrates.

A controller may comprise one or more programs or routines for controlling designed subsystems associated with a fabrication tool. Examples of such programs or routines include a substrate positioning program, a process gas control program, a pressure control program, a heater control program, and a plasma control program. A substrate positioning program may include program code for process tool components that are used to load the substrate onto a pedestal and to control the spacing between the substrate and other parts of a fabrication tool. A positioning program may include instructions for moving substrates in and out of the reaction chamber to deposit films on substrates and clean the chamber.

A process gas control program may include code for controlling gas composition and flow rates and for flowing gas into one or more process stations prior to deposition to bring about stabilization of the pressure in the process station. In some implementations, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing numbers of cycles on one or more substrates during the processing of the batch.

A heater control program may include code for controlling the current to a heating unit that is used to heat the substrate. Alternatively, the heater control program may control delivery of a heat transfer gas (such as helium) to the substrate.

In some implementations, there may be a user interface associated with a controller. The user interface may include a display screen, graphical software displays of the apparatus and/or process conditions, and user input devices such as pointing devices, keyboards, touch screens, microphones, etc.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

The system software may be organized in many different ways that may have different architectures. For example, various chamber component subroutines or control objects may be written to control operation of the chamber components necessary to carry out the deposition processes (and other processes, in some cases) in accordance with the disclosed embodiments.

### ADDITIONAL CONSIDERATIONS

Without limitation, example systems may include a plasma etch chamber or module, a plasma-assisted deposition chamber or module such as a plasma-assisted chemical vapor deposition (PECVD) chamber or module or a plasma-assisted atomic layer deposition (PEALD) chamber or module, an atomic layer etch (ALE) chamber or module, a clean chamber or module, a physical vapor deposition (PVD) chamber or module, an ion implantation chamber or module, and any other plasma-assisted semiconductor processing systems that may be associated or used in the fabrication and/or manufacturing of semiconductor wafers.

Unless otherwise specified, the plasma power levels and associated parameters provided herein are appropriate for processing a 300 mm wafer substrate. One of ordinary skill in the art would appreciate that these parameters may be adjusted as necessary for substrates of other sizes.

The apparatus/process described herein may be used in conjunction with lithographic patterning tools or processes, for example, for the fabrication or manufacture of electronic devices including semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool: (2) curing of photoresist using a hot plate or furnace or UV curing tool: (3) exposing the photoresist to visible or UV or x-ray light with a tool such as a wafer stepper: (4) developing the resist so as to selectively remove resist and thereby pattern it using a tool such as a wet bench: (5) transferring the resist pattern into an underlying film or workpiece by using a dry or plasma-assisted etching tool: and (6) removing the resist using a tool such as an RF or microwave plasma resist stripper.

As used in this specification and appended claims, the singular forms “a”, “an”, and “the” include plural referents unless the content and context dictates otherwise. For example, reference to “a cell” includes a combination of two or more such cells. Unless indicated otherwise, an “or” conjunction is used in its correct sense as a Boolean logical operator, encompassing both the selection of features in the alternative (A or B, where the selection of A is mutually exclusive from B) and the selection of features in conjunction (A or B, where both A and B are selected).

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware—for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A system comprising:
a process chamber, comprising a chamber wall, a plasma source, and at least two stations, wherein each station comprises a wafer support;
a first camera sensor optically coupled to a first optical access port of a first station of the process chamber;
a second camera sensor is optically coupled to the first optical access port of the process chamber or a second optical access port of the process chamber; and
logic configured to process signals from the first camera sensor and the second camera sensor to characterize one or more properties of a plasma in at least the first station of the process chamber.

2. The system of claim 1, wherein the logic is further configured to account for a feature of at least the second station of the process chamber.

3. The system of claim 1, wherein the process chamber comprises four stations.

4. The system of claim 1, further comprising an optical fiber and/or a light pipe that optically couples the first camera sensor to the first optical access port.

5. The system of claim 4, further comprising a second optical fiber and/or a second light pipe that optically couples the first camera sensor to the second optical access port.

6. The system of claim 4, wherein the first optical access port is an optical lens.

7. The system of claim 4, wherein the first optical access port comprises a window having a maximum cross-sectional dimension of at most about 5 mm.

8. The system of claim 1, wherein the logic is configured to process the signals from the first camera sensor and from the second camera sensor in a multi-threaded process.

9. The system of claim 1, further comprising an edge computer for the process chamber, wherein the logic comprises instructions for executing on the edge computer.

10. (canceled)

11. The system of claim 10, wherein the location comprises at least one of: a centroid of the plasma within the process chamber and/or within the first station; a point or boundary having defined spectral characteristics of the plasma; or
an integrated or summed optical intensity over a bounded region of interest within a field of view of the first camera sensor.

12. (canceled)

13. (canceled)

14. The system of claim 1, wherein the one or more properties of the plasma comprise at least one of: a pulse characteristic of the plasma; an identification of parasitic plasma; an identification of hollow cathode discharge; or a location of the plasma within the process chamber and/or within at least the first station.

15. (canceled)

16. (canceled)

17. The system of claim 1, wherein the logic is configured to characterize the one or more properties of the plasma in the first station of the process chamber and wherein the logic is configured to account for a structural feature located in the second station of the process chamber.

18. The system of claim 17, wherein the structural feature located in the second station of the process chamber is on a line of sight from the optical access port of the first station that passes through at least a portion of the first station and at least a portion of the second station.

19. The system of claim 1, further comprising a non-camera sensor, and wherein the logic is configured to employ signals from the non-camera sensor to characterize the one or more properties of a plasma in the process chamber.

20. The system of claim 1, wherein the first camera sensor is located and/or oriented to capture first images from a first location or a first angle within the process chamber, and wherein the second camera sensor is located and/or oriented to capture second images from a second location or a second angle within the process chamber.

21. (canceled)

22. The system of claim 1, wherein the logic is configured to characterize pulses of the plasma.

23. The system of claim 1, further comprising a light source configured to provide lighting in the process chamber while the one or more camera sensors acquire images of the process chamber.

24. The system of claim 23, further comprising logic to synchronize the light source and the one or more camera sensors so that the one or more camera sensors acquire the images of the process chamber while the light source illuminates an interior region of the process chamber.

25. The system of claim 1, wherein the first camera sensor is configured to capture indirect optical information from within the process chamber.

26. The system of claim 1, wherein the logic is further configured to locate an edge of a process chamber component and/or an edge of the plasma from one or more images provided by the first camera sensor.

27. The system of claim 1, wherein the logic is further configured to use the one or more properties of the plasma to diagnose an actual or potential failure or fault with a component of the process chamber.

28. The system of claim 1, wherein the logic is further configured to use the one or more properties of the plasma to characterize a process condition within the process chamber.

29. The system of claim 28, wherein the logic is further configured to modify an operation in the process chamber based on the process condition within the process chamber.

30. The system of claim 28, wherein the process condition is a process gas composition, a process gas flow characteristic, a pressure within the process chamber, a temperature of one or more components of the process chamber, a plasma power, a plasma frequency, a geometric characteristic of any of the one or more components of the process chamber, or any combination thereof.

31. A method comprising:
obtaining a first image from a first camera sensor, wherein the first image is of at least a portion of a first station of a process chamber, wherein the process chamber comprises a chamber wall, a plasma source, and at least two stations, each comprising a wafer support;
obtaining a second image from a second camera sensor, wherein the second image is of a second region of the process chamber; and
characterizing one or more properties of a plasma in at least the first station of the process chamber, wherein the characterizing is based on the first image and the second image.

32. The method of claim 31, wherein characterizing the one or more properties of the plasma in at least the first station comprises identifying one or more contours of elements associated with the first station in the first image and/or the second image.

33. The method of claim 32, wherein the one or more elements comprise: a showerhead in the first station, a pedestal in the first station, chamber walls of the first station, or any combination thereof.

34. The method of claim 32, wherein the one or more properties comprise identification of hollow cathode discharge (HCD) occurrences, and wherein the method further comprises clustering pixels of the first image and/or the second image into a plurality of categories, at least one category of the plurality of categories corresponding to HCD occurrences.

35. The method of claim 31, wherein characterizing the one or more properties of the plasma comprises providing the first image and/or the second image to a trained machine learning model configured to perform segmentation on the first image and/or the second image.

36. The method of claim 35, wherein the trained machine learning model is a U-Net architecture.

37.-40. (canceled)
